(19) United States
(12) Patent Application Publication
(10) Pub. No.: US 2005/0053183 A1
(43) Pub. Date: Mar. 10, 2005

(54) Paper sheet identifying and counting machine and method for identifying and counting paper sheet

(75) Inventors: Hideo Abe, Tokyo (JP); Yoshikazu Takagi, Yokohama-Shi (JP); Hiroyuki Shimada, Kawasaki-Shi (JP); Makoto Shinkai, Yokohama-Shi (JP); Takahiro Ogawa, Kawasaki-Shi (JP)

Correspondence Address: OBLON, SPIVAK, MCCLELLAND, MAIER & NEUSTADT, P.C., 1940 DUKE STREET, ALEXANDRIA, VA, 22314, US

(73) Assignee: Billcon Corporation, Tokyo (JP)

(21) Appl. No.: 10/497,157

(22) PCT Filed: Dec. 5, 2002
(86) PCT No.: PCT/JP02/12764

(30) Foreign Application Priority Data
Dec. 7, 2001 (JP) 2001-374929

(51) Int. Cl. H03K 25/00

(52) U.S. Cl. 377/94

(57) ABSTRACT

A sheet discriminating/counting machine selects sheets to be discriminated of a predetermined country or region by discrimination object selecting means, transports the sheets to be discriminated at high speed along a transporting path, and performs sheet discriminating/counting processing at a sheet discriminating/counting unit disposed along the transporting path. The sheet discriminating/counting machine comprises: a hopper to which sheets to be discriminated are supplied; a sheet transporting device for transporting sheets supplied to the hopper one by one along a transporting path with the shorter side of each sheet parallel to the transporting direction; a sheet discriminating unit disposed along the transporting path for discriminating/counting sheets; and a stacker upon which sheets fed out from the transporting path are stacked. The transporting path is provided with a curved transporting region which is curved in a U-shape partway and has a reject transport path connected to a pocket from a the subsequent downstream side transporting path. The sheet discriminating/counting machine performs discrimination processing of 1200 sheets or more per minute and has one stacker and one pocket.

### TECHNICAL FIELD

The present invention relates to a sheet discriminating/counting machine for discriminating and counting sheets of multiple countries or regions, and a discriminating/counting method thereof, particularly to a desk-top bill discriminating/counting machine for discriminating denominations of bills of multiple countries or regions, and counting the bills thereof at a high speed and to a discriminating/counting method thereof.

### BACKGROUND ART

Conventionally, as such types of sheet discriminating/counting machines, desk-top bill discriminating/counting machines are known, which discriminate denominations of bills and count bills.

This desk-top bill discriminating/counting machine includes a hopper on the front portion of the top of the main unit thereof for supplying and stacking bills of a predetermined country which are to be discriminated. Upon starting the bill discriminating/counting machine, each of the bills stacked on the hopper are fed out one by one by a feed roller. The bills thus fed out are transported one by one through a transporting path within the main unit of the counting machine with the shorter side of each bill parallel to the transporting direction and are subjected to discriminating processing for denominations of bills of the predetermined country or discriminating processing whether each bill is genuine or forged, as well as counting the number of bills and the sum of the money, by a discriminating unit disposed at a predetermined position on the transporting path.

Each bill thus subjected to the discriminating processing for the kind thereof and counting processing passes on downstream the transporting path and is guided to a stacker where the user can take out the output bills.

Such a conventional bill discriminating/counting machine has a configuration wherein each bill of the predetermined country fed out from the hopper is completely flipped over by the feeding roller, following which the bill is guided to the stacker through the generally straight transporting path, wherein the discriminating unit is disposed at a predetermined position on the straight transporting path (see U.S. Pat. No. 5,912,982, and U.S. Pat. No. 5,692,067).

Conventional bill discriminating/counting machines have a configuration wherein the transporting path for transporting bills from the feeding roller up to the stacker is formed generally straight, leading to difficulty in forming the transporting path with a sufficient length. In particular, conventional small-sized compact desk-top bill discriminating/counting machines are formed with a small length of the transporting path, and accordingly, this configuration necessitates low-speed discriminating/counting processing for bills at a rate of around 700 to 800 sheets per minute, leading to difficulty of high-speed processing.

Furthermore, with such a bill discriminating/counting machine, it is required to pick out forged bills, damaged bills, bills of other countries and the like so as to be rejected from the bills which have been subjected to the discriminating/counting processing. Accordingly, such a bill discriminating/counting machine has a configuration wherein an rejecting mechanism included therein acts upon the bill which is to be rejected after discrimination of the bill by the discriminating unit while tracking the timing of the bill which is to be rejected passing through the transporting path, leading to the need of forming the transporting path with a length corresponding to a period of time from detection of the bill which is to be rejected up to the action of the rejecting mechanism. It is to be noted that a predetermined period of time is required for processing discrimination signals from the discriminating unit, actions of the rejecting mechanism, and the like. The higher the processing speed of the bill discriminating/counting machine is, the greater the distance over which the bill is transported in the aforementioned required period of time is.

A small-sized desk-top bill discriminating/counting machine has difficulty in including a transporting path with a sufficient length downstream from the discriminating unit, leading to difficulty in improving the counting rate of bills. Specifically, conventional small-sized desk-top bill discriminating/counting machines exhibit poor performance of a rate of around 700 to 800 sheets of processed bills per minute, and even the highest-performance one exhibits performance of a rate of around 1000 sheets thereof per minute.

On the other hand, there are various paper conditions of bills such as creased bills, bills with folded corners, and the like. In the event that bills in such conditions are guided to the transporting path, such bills may cause jamming at any portions on the transporting path. Accordingly, it is necessary for the bill discriminating/counting machine to include a jamming preventing/restoring mechanism as a measure for preventing or recovering the bill from jamming and for immediately stopping transporting of bills so as to enable removal of the jammed bill with simple operations.

However, conventional bill discriminating/counting machines have only poor-performance jamming preventing/restoring mechanism, leading to a problem that in the event of jamming of bills on the transporting path, it is difficult to remove jammed bills with simple operations.

Furthermore, the discriminating unit performs discrimination of bills by detecting a particular part of each bill, leading to defects or inconveniences that bills of countries other than a predetermined country can not be discriminated, it is difficult to improve discrimination performance for bills, and conventional bill discriminating/counting machines are not widely applicable. Accordingly, conventional bill discriminating/counting machines can only perform counting of bills of a predetermined country, and in a case of discriminating/counting processing for bills of another country, it is necessary to replace the discriminating unit by one prepared for discriminating a particular part of bills of the other country.

On the other hand, bills circulate through the hands of many people, and accordingly, there are soiled bills and bills contaminated by pathogen such as viruses due to use of persons in various occupations, and even sick persons. For persons engaged in financial business, money handling, or the like, all bills are preferably new and clean, but this is actually unrealistic.

The present invention has been made in order to solve the defects or inconveniences mentioned above, and accordingly, it is an object thereof to provide a small-sized compact desk-top sheet discriminating/counting machine for performing discrimination and counting processing for sheets of multiple countries and regions at a high processing rate, and to provide a discriminating/counting method thereof.

It is another object of the present invention to provide a sheet discriminating/counting machine having an efficient configuration wherein a transporting path is efficiently formed within the main unit thereof for performing discrimination and counting processing for sheets of multiple countries and regions at a high processing rate, and to provide a discriminating/counting method thereof, even in a case of a small-sized compact desk-top sheet discriminating/counting machine.

It is a further object of the present invention to provide a sheet discriminating/counting machine having a configuration wherein a stacker and a pocket are included on the front surface of the main unit thereof for removing the sheets which have been rejected from discriminating/counting processing on the transporting path to the pocket, and storing the rejected sheets in the pocket, and a discriminating/counting method thereof.

It is still further object of the present invention to provide a sheet discriminating/counting machine for sterilizing the transported sheets on the transporting path, thereby providing sense of security to the user, and thereby keeping the sheets subjected to discriminating/counting processing clean, and to provide a discriminating/counting method thereof.

It is still further object of the present invention to provide a sheet discriminating/counting machine for performing discriminating/counting processing for sheets at a transporting speed corresponding to a processing rate of 1200 sheets or more per minute, and having a configuration wherein in a case of jamming of sheets on the transporting path, the transporting path is easily restored, and to provide a discriminating/counting method thereof.

It is still further object of the present invention to provide a sheet discriminating/counting machine having a configuration wherein in a case of jamming of sheets on the transporting path, jammed sheets can be easily removed with simple operations.

It is still further object of the present invention to provide a sheet discriminating/counting machine including a computing CPU as well as a control CPU, for reducing the processing load of the control CPU, thereby improving discriminating/counting processing speed.

### DISCLOSURE OF THE INVENTION

To solve the above-described problems, the sheet discriminating/counting machine according to the present invention comprises: a hopper to which sheets to be discriminated are supplied; a sheet transporting device for transporting sheets supplied to the hopper, one at a time, along a transporting path with the shorter side of each sheet parallel to the transporting direction; a sheet discriminating unit disposed along the transporting path, for discriminating/counting sheets; a stacker upon which sheets fed out from the transporting path are stacked; and discrimination object selecting means for selecting a discriminating program, for performing discrimination processing of the sheets to be discriminated; wherein the transporting path comprises a curved transporting region which is curved in a U-shape, along the way from the hopper to the stacker.

With the sheet discriminating/counting machine according to the present invention, the discrimination object selecting means may include: activation-time discrimination object selecting means for selecting and setting a discriminating program in order to determine sheets to be discriminated at the time of activation; and in-operation discrimination object switching means for selectively switching discriminating programs for discrimination processing of desired sheets to be discriminated during operation; and control processing of a control CPU and discrimination processing of a computation CPU are respectively executed based on a control program and a selected discriminating program.

Furthermore, the hopper may be formed on the apex of the counting machine main unit, the stacker is formed on the lower front portion of the counting machine main unit, the U-shaped curved transporting region is formed at the lower rear side of the counting machine main unit, and the transporting path includes a combination of a straight transporting path from the hopper to the U-shaped curved transporting region, the U-shaped curved transporting region, and a downstream side transporting path from there to the stacker. The machine may be also provided with a sheet discriminating unit for performing discriminating/counting and genuine/forged determination of sheets, disposed along the straight transporting path, and the sheet discriminating unit is provided with a line sensor so as to traverse the transporting path, in which the line sensor is a photo-transmission sensor in which a projection side sensor member and reception side sensor member are assembled so as to be separable in two, configured so as to perform discriminating scanning of the entire surface of sheets transported along the transporting path by repeating the line scanning. The machine may further include a rear side transporting path opening mechanism is provided at the rear side of the straight transporting path, disposed around a lower support shaft of the counting machine main unit, the rear side transporting path opening mechanism comprising a rear opening guide arm mechanism turnable around a support shaft provided to the lower front side of the U-shaped curved transporting region, and the opening guide arm mechanism comprising guide plates making each of the straight transporting path and the U-shaped curved transporting region so as to be opened.

Still furthermore, according to the sheet discriminating/ counting machine of the present invention, the downstream side transporting path is crest-shaped, a crest-shaped transporting path opening mechanism capable of turning on a lower support shaft of the counting machine main unit is disposed below the downstream side transporting path, with the crest-shaped transporting path opening mechanism comprising a front opening guide arm mechanism turntable on a support shaft provided at the lower front side of the U-shaped curved transporting region, and the opening guide arm mechanism comprising a guide plate making up the downstream side transporting path so as to be opened, and also, the downstream side transporting path is crest-shaped, a reject transporting path opening mechanism which enables opening of a reject transporting path is provided below a reject transporting path branching from the apex side of the downstream side transporting path, and the reject transporting path opening mechanism comprises a opening guide arm mechanism provided turnably around a center-lower side support shaft of the counting machine main unit, with the opening guide arm mechanism comprising a guide plate making up the reject transporting path so as to be opened.

Furthermore, in order to solve the above-described problems, the sheet discriminating/counting machine according to the present invention comprises: a hopper to which sheets to be discriminated and counted are supplied; a sheet transporting device for transporting sheets supplied to the hopper one by one along a transporting path with the shorter side of each sheet parallel to the transporting direction; a sheet discriminating unit disposed along the transporting path, for discriminating/counting sheets; a sterilizing processing device disposed along the transporting path, for sterilizing or disinfecting processing of the transported sheets; and a stacker upon which sheets fed out from the transporting path are stacked; in which the transporting path is provided with a curved transporting region which is curved in a U-shape, along the way from the hopper to the stacker.

Furthermore, in order to also solve the above-described problems, the sheet discriminating/counting method according to the present invention is a method comprising the steps of: selecting a discriminating program, by discrimination object selecting means, corresponding to sheets to be discriminated in order to perform discrimination processing of desired sheets to be discriminated; feeding sheets, to be discriminated, stacked onto a hopper on a transporting path by a feeding mechanism at a feeding rate of 1200 sheets per minute or faster, in order to perform discrimination processing of the sheets to be discriminated with a computation CPU, based on the control processing of a control CPU and the selected discriminating program; guiding the fed sheets to, a straight transporting path descending along a rear side of the counting machine main unit; performing discrimination/counting and genuine/forged determination of the sheets by a sheet discrimination unit based on the discriminating program of the computation CPU while the sheets passing through the straight transporting path; guiding the sheets subjected to discrimination/counting by the sheet discrimination unit to a downstream side transporting path through a U-shaped curved transporting region at the lower rear side of the counting machine main unit; and stacking the sheet sent out from the downstream side transporting path to a stacker.

In the sheet discriminating/counting method according to the present invention described above, the downstream side transporting path may be a crest-shaped transporting path and a reject transporting path branches from the apex thereof, and sheets which are not the object of discrimination among the sheets subjected to discrimination/counting at the sheet discrimination unit are guided to the reject transporting path, sent out to the pocket, and stacked. Furthermore, in this method, during the operation of the sheet discriminating/counting machine, the discriminating program recorded in SRAM is switched over by in-operation discrimination object switching means, and on the other hand, discrimination processing of the computation CPU based on the discriminating program switched over and control processing of the control CPU based on the control program are performed, thereby performing discrimination/counting processing of the sheets transported along the transporting path.

With the sheet discriminating/counting machine and sheet discriminating/counting method according to the present invention described above, sheets from various countries or regions can be subjected to the discriminating/counting processing, and further, the space formed inside the counting machine main unit is effectively and aggressively used as a transporting path so that the length of the transporting path can be made sufficiently long, whereby the sheet discriminating/counting machine can be made small and compact, and on the other hand, sheets can be subjected to the sheet discriminating/counting at high speed even with small and compact sheet discriminating/counting machines.

Furthermore, by configuring a straight transporting path following the rear side within the counting machine main unit, a U-shaped curved transporting region and the lower rear side of the counting machine continuing on from this transporting path, and a downstream side transporting path from this curved transporting path to the stacker, a sufficient transporting length can be ensured to be realized within the counting machine main unit, so that sheets can be subjected to the sheet discriminating/counting processing at high speeds.

Still furthermore, the sheet discriminating/counting machine according to the present invention comprises a sheet discriminating unit on the straight transporting path so as to not obstruct transporting of sheets, and on the other hand, has a great radius of curvature for the U-shaped curved transporting path so as to efficiently and effectively prevent the sheet jamming phenomenon, and the sheet discriminating/counting machine comprises a rear side transporting path opening mechanism, crest-shaped transporting path opening mechanism, and a reject transporting path opening mechanism, so that the straight transporting path, U-shaped curbed transporting path, and downstream crest-shaped transporting path and reject transporting path can be widely opened, whereby jammed sheets and residual sheets can be extracted and removed in a simple and easy manner by opening the transporting paths.

Still furthermore, the sheet discriminating/counting machine according to the present invention comprises a photo-transmission type line sensor making up the sheet discriminating unit on the straight transporting path so as to traverse the transporting path, the photoreceptor rows of the line sensor are serially scanned with a scanning processing circuit, and by repeating this serial scanning, the speedy and precise scanning of the entire surface of the sheets can be made, so that sheet discriminating/counting, and further, denomination determination and counting of bills, detection of whether the bill is whole or not, whether the bill is folded or not, and so forth, can be performed in an accurate and speedy manner.

At this time, the inspection data from the line sensor has been relegated to a computation CPU which is separately provided from the control CPU, so that the inspection data is computed with the calculation-dedicated computation CPU and high-speed processing is enabled, and also, the load on the control CPU can be reduced, thereby handling increased speeds of sheet discriminating/counting processing.

Moreover, with the sheet discriminating/counting machine according to the present invention, a control CPU and computation CPU are included, so that a part of the control CPU is handed by the computation CPU, thereby reducing the processing load of the control CPU, whereby the discriminating/counting processing speed can be improved, and also the processing load on the control CPU is even further reduced, so that the speed of the sheet discrimination processing can be increased even further.

### BRIEF DESCRIPTION OF THE DRAWINGS

FIG. 1 is a perspective view illustrating an embodiment of a bill discriminating/counting machine as a sheet discriminating/counting according to the present invention.

FIG. 2 is a left side view illustrating a machine chamber with the left side cover of the bill discriminating/counting machine shown in FIG. 1 removed.

FIG. 3 is a right side view illustrating a control chamber with the right side cover of the bill discriminating/counting machine removed.

FIG. 4 is a schematic cross-sectional view illustrating a transporting path configuration formed within the bill discriminating/counting machine shown in FIG. 1.

FIG. 5 is a diagram illustrating a sending roller provided to a sending mechanism of the bill discriminating/counting machine shown in FIG. 1.

FIG. 6 is a diagram illustrating a feeding roller provided to a feeding mechanism of the bill discriminating/counting machine shown in FIG. 1.

FIG. 7 is a configuration diagram which shows a rear cover and a rear-side transporting path opening mechanism of the bill discriminating/counting machine.

FIG. 8 is a diagram which shows the rear-side transporting path opening mechanism, in a locked state, included in the bill discriminating/counting machine.

FIG. 9 is a diagram which shows the rear-side transporting path opening mechanism, in a lock-released state (open state), included in the bill discriminating/counting machine.

FIG. 10 is a diagram which shows an on/off state of the crest-shaped transporting path opening mechanism included in the sheet discriminating/counting machine.

FIG. 11 is a diagram which shows an on/off state of the reject transporting path opening mechanism included in the sheet discriminating/counting machine.

FIG. 12 is a diagram which shows a pocket opening cam mechanism for releasably locking the reject transporting path opening mechanism in the locked state.

FIG. 13 is a diagram which shows the pocket opening cam mechanism in the lock-released state.

FIG. 14 is a diagram which shows an engaging hook of the pocket opening cam mechanism.

FIG. 15 is a diagram which shows the transporting path configuration formed within the bill discriminating/counting machine and the sensor layout configuration.

FIG. 16 shows the reflection-light front/back discriminating sensor included in the bill discriminating/counting machine and is a diagram taken along the line XVI-XVI in FIG. 4.

FIG. 17 is a plan view which shows a line sensor serving as a sheet discriminating unit included in the bill discriminating/counting machine.

FIG. 18 is a front view of the line sensor shown in FIG. 18.

FIG. 19 is a diagram which shows the line sensor taken along the line XIX-XIX in FIG. 18.

FIG. 20 is a diagram which shows the line sensor taken along the line XX-XX in FIG. 19.

FIG. 21 is a diagram which shows a magnetic sensor (MG sensor) serving as a genuine/forged discriminating sensor of the sheet discriminating unit.

FIG. 22 is a diagram which shows a circuit board stored in a side space in the bill discriminating/counting machine shown in FIG. 1.

FIG. 23 is a configuration diagram which shows a circuit configuration for switching discriminating programs of the bill discriminating/counting machine shown in FIG. 1.

FIG. 24 is a diagram which shows an autonomous rotation control circuit for controlling rotation of the transporting driving motor included in the bill discriminating/counting machine shown in FIG. 1.

FIG. 25 is a diagram which shows the relation between: line scanning by the line sensor forming the discriminating unit of the bill discriminating/counting machine; and timing.

FIG. 26 is a functional block diagram for serial scanning of the aforementioned line sensor.

FIG. 27 is a timing chart for serial scanning of the aforementioned line sensor.

FIG. 28 is a flowchart for switching the discriminating programs at the time of turning on the power supply of the bill discriminating/counting machine.

FIG. 29A is a diagram which shows a modification of the feeding roller included in the feeding mechanism of the bill discriminating/counting machine, and FIG. 29B is a cross-sectional diagram taken along the line XXIXB-XXIXB in FIG. 29A.

FIG. 30 is a flowchart which shows a switching method for switching the discriminating programs during operations of the bill discriminating/counting machine.

FIG. 31 is a diagram which shows a sheet discriminating/counting machine according to another embodiment of the present invention.

FIG. 32 is a side cross-sectional view of a sterilizing device included in the sheet discriminating/counting machine shown in FIG. 31.

### BEST MODE FOR CARRYING OUT THE INVENTION

Description of an embodiment according to the present invention will be made hereunder with reference to the accompanying drawings.

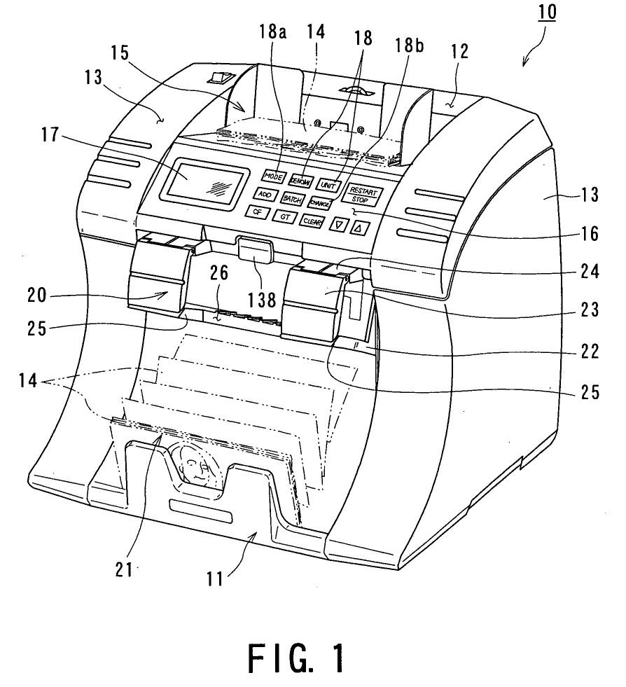

FIG. 1 is an overall perspective view which shows a sheet discriminating/counting machine according to an embodiment of the present invention, e.g., a desk-top bill discriminating/counting machine having processing performance for performing discriminating/counting processing for bills, for example, as sheets, at a high processing rate of 1200 sheets or more per minute.

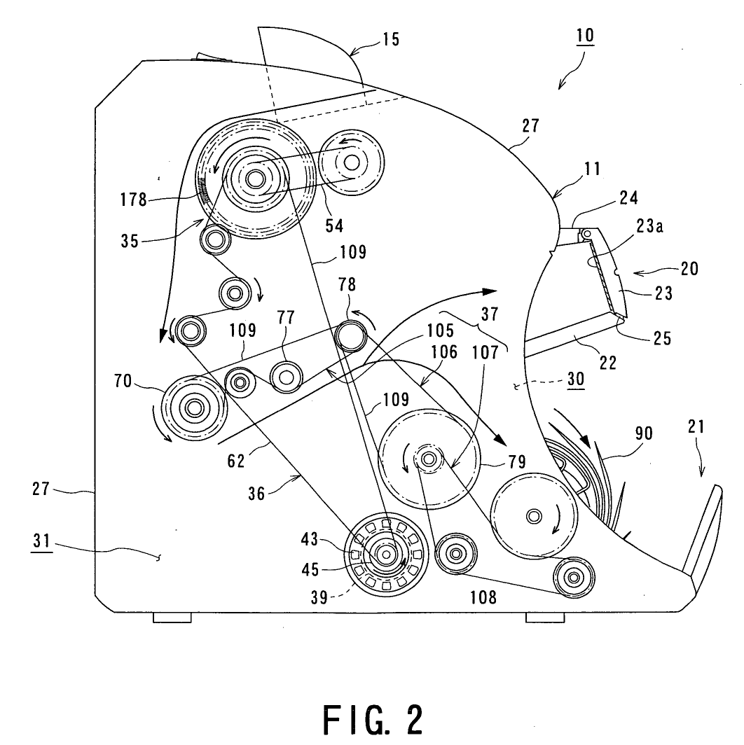

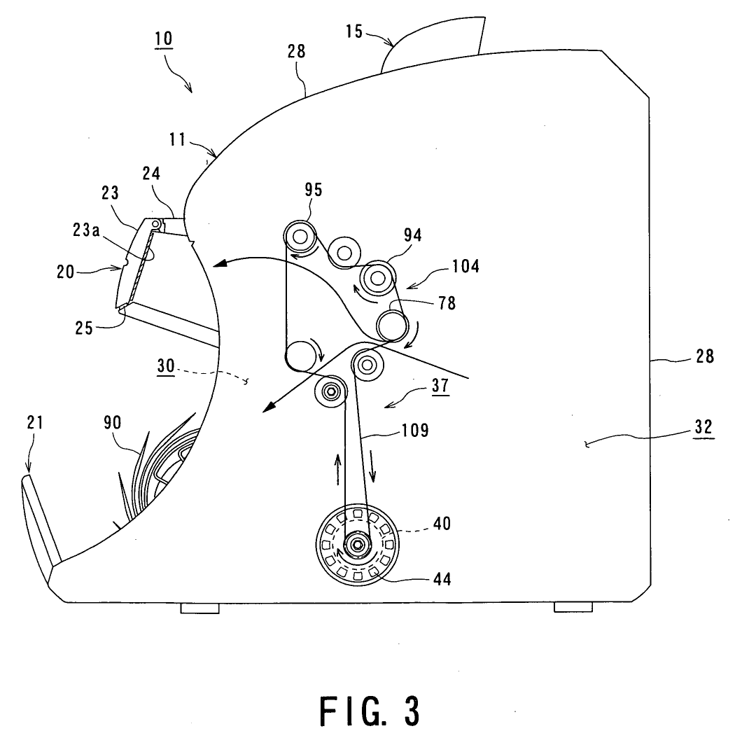

The bill discriminating/counting machine 10 has a body having curved surfaces, formed generally in the shape of a deformed box, and the top and both sides of a counting-machine main unit 11 are covered with a top cover 12 and side covers 13 and 13 formed of resin. The top cover 12 is formed in the shape of a curved surface smoothly curved downward from the rear surface to the front surface such that the front end and both side ends continue to the side covers 13 and 13. The front ends of the side covers 13 and 13 are formed in the shape of a smoothly recessed arc, whereby the bill discriminating/counting machine 10 is formed with the outline from the top on to the front surface generally in the shape of a “S” as viewed from the side as shown in FIG. 2 and FIG. 3.

The bill discriminating/counting machine 10 integrally comprises a hopper 15 on the front portion of the top of the counting-machine main unit 11 for supplying bills 14 which are to be counted as paper sheets, an operation panel 16 for operating the bill discriminating/counting machine 10, and a full-graphic display panel 17 such as LCD or the like, for displaying discriminating/counting results, included on the front surface of the top cover 12, as shown in FIG. 1. The operation panel 16 includes multiple, e.g., twelve operation buttons or operation keys 18, arrayed thereon, which the user can operate so as to perform discriminating/counting processing for the bills 14 of multiple countries or regions, e.g., two countries, in a desired mode selected from various counting modes.

Furthermore, the bill discriminating/counting machine 10 includes a pocket 20 on the front surface thereof for stacking paper sheets such as bills or the like which have been rejected from discriminating/counting processing, and a stacker 21 on the lower portion thereof for stacking bills after discriminating/counting processing.

The pocket 20 is formed so as to protrude from the front surface of the bill discriminating/counting machine 10, i.e., formed with an open end having a simple configuration, thereby facilitating the taking-out of the stacked paper sheets or the like. Specifically, the pocket 20 includes a plate-shaped pocket receiver 22 for stacking sheets or the like and a support member 23 detachably mounted to the front end of the pocket receiver 22. The support member 23 includes an elastic member 23a (see FIG. 2 and FIG. 3) adhering to the inner surface thereof for preventing noise and damage of the sheets or the like. The support member 23 is turnably supported by a free end of a pocket arm 24 in the shape of a cantilever protruding forward from the counting-machine main unit 11 of the bill discriminating/counting machine 10, and the lower end thereof is fixed to the front end of the pocket receiver 22 with fixing means 25 such as a magnet with simple operation. The middle portion of the pocket receiver 22 is cut off so as to form an opening 26 on the front portion thereof, wherein such a configuration including the opening 26 and the supporting member 23 having an opening facilitates the taking-out of the sheets stacked on the pocket 20. An arrangement may be made wherein the support member 23 is fixed to the bill discriminating/counting machine 10 such that the lower end thereof is supported by the front end of the pocket receiver 22 and the upper end thereof is detachably fixed to the pocket arm 24.

As shown in FIG. 2 and FIG. 3, the counting-machine main unit 11 of the bill discriminating/counting machine 10 includes left and right main unit plates 27 and 28 having a function serving as a partition for dividing the space therein, wherein the space within the discriminating/counting machine 10 is divided into a main space 30 on the middle portion thereof and left and right side space 31 and 32. Further, the side spaces 31 and 32 are formed between the main unit plate 27 and the side cover 13 and between the main unit plate 28 and the side cover 13, respectively. One of the side spaces 31 and 32 is used as a machine chamber for the power transmission, and the other is used for a control chamber for the control operations of the bill discriminating/counting machine 10.

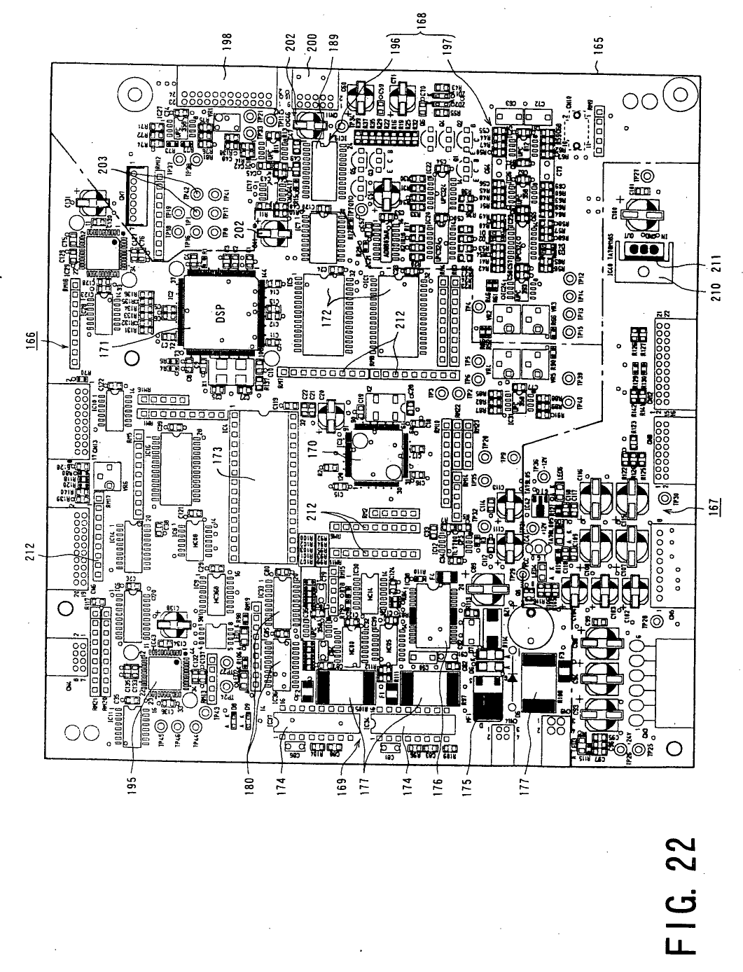

As shown in FIG. 2, the left side space 31 serving as a machine chamber stores a feeding power transmission mechanism 36 for driving a sheet feeding driving system 35 and a transporting power transmission mechanism 38 for driving a sheet transporting driving system 37. On the other hand, the right side space 32 serving as a control chamber stores a circuit board 165 (see FIG. 22) in a space therein for controlling and driving the bill discriminating/counting machine 10, as well as including a part of the transporting power transmission mechanism 38.

The bill discriminating/counting machine 10 includes two driving sources on the middle portion of the bottom of the counting-machine main unit 11 thereof. One of the driving sources is a feeding driving motor 39, and the other one is a transporting driving motor 40. Although there is no need to drive both the driving motors 39 and 40 synchronously with each other, the same type of motors may be employed so as to generally match the motor rotating speed thereof. The rotating speeds of both the driving motors 39 and 40 are measured by encoders 43 and 44, and the feeding driving motor 39 includes a brake device 45 such as an electromagnetic brake, a mechanical brake, or the like, for immediately stopping rotation of the motor.

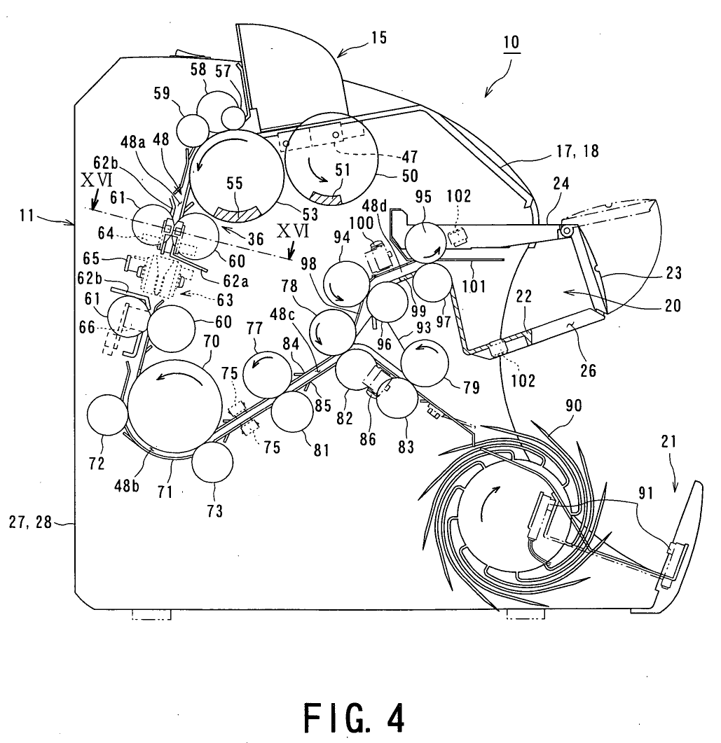

On the other hand, the counting-machine main unit 11 of the bill discriminating/counting machine 10 includes a reflection hopper sensor 47 on the bottom of the hopper 15 for monitoring presence or absence of the bills stacked on the hopper 15 as shown in FIG. 4. The bills stacked on the hopper 15 are sent to a transporting path 48 one by one by a sending mechanism. Further, it is to be noted that a sending roller 15 forming a pair with another roller is disposed on the bottom of the hopper 15, serving as a sending mechanism, for example. A part of the outer surface of the sending roller 50 is replaced by a friction member 51 formed of urethane rubber or the like, and has a configuration wherein the bottom-most bill stacked on the bottom of the hopper 15 is sent toward the entrance of the transporting path 48 for each rotation of the sending roller 50.

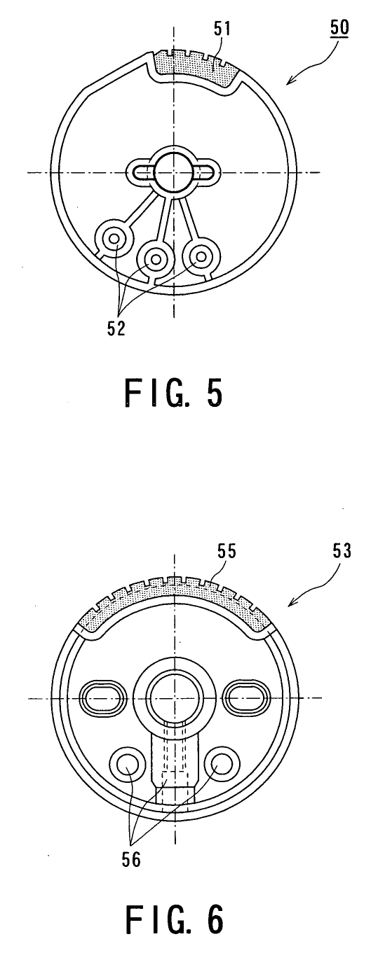

The bill sent by the sending roller 50 with the shorter side thereof parallel to the transporting direction is fed out by a feeding roller or a feeding drum 53 serving as a feeding mechanism. The feeding roller 53 and the sending roller 30 are driving rollers with a diameter of 50 mm, for example, and are rotationally driven synchronously with a timing belt 54 (see FIG. 2). A part of the outer surface of the feeding roller 54 is surely replaced by a friction member 55 for transporting each bill. The friction member 55 is formed with a length in the circumferential direction of 39 mm to 66 mm, for example, which is greater than with the friction member 51 having the length in the circumferential direction of 7 to 15 mm, for example, formed on the outer surface of the sending roller 50. As shown in FIG. 5 and FIG. 6, the feeding roller 53 and the sending roller 50 include balancer weights 52 and 56, respectively, at positions across the friction members 51 and 55 in the diameter directions so as to prevent rotational unbalance due to the friction members 51 and 55 secured thereon, thereby keeping rotation balance.

Furthermore, a support roller 57 serving as a friction roller, a stop roller 58 serving as a stop member for preventing the doubled bills from being sent, and a pinch roller 59 serving as a pressing roller, are provided in that order in rotational direction of the feeding roller 53. Of these rollers, the stop roller 58 is a non-rotating roller with great friction formed of urethane rubber or the like, and it forms, together with the feeding roller 53, a mechanism for preventing two bills from being sent together.

The bill fed to the transporting path 48 by the feeding roller 53 is guided to a downward straight transporting path formed on the rear side of the counting-machine main unit 11 of the counting machine by the transporting force applied from the pinch roller 59 while preventing the feeding of two bills by the stop roller 58. The pinch roller 58 is pressed into contact with the feeding roller 53 by an elastic member such as a spring or the like for applying the transporting force to each bill.

A straight transporting path 48a formed downward from the feeding roller 53 extends around the lower portion of the main unit along the rear surface of the counting-machine main unit 11 of the counting machine, and leads to a U-shaped curved transporting path 48b as shown in FIG. 4. Furthermore, plural pairs of transporting driving rollers 60 and transporting driven rollers 61 are included along the straight transporting path 48a such that each driving roller 60 faces the corresponding driven roller 61. Each transporting driven roller 61 is formed of a pinch roller elastically pressed into contact with the corresponding transporting driving roller 60 by the force of a spring. The straight transporting path 48a is divided by a stationary-side guide plate 62a and a movable-side guide plate 62b, wherein each bill is transported while being supported by the multiple pairs of the transporting driving rollers 60 and the transporting driven rollers 61.

In this case, the feeding roller 53 and the transporting driving rollers 60 and 60 are arrayed on one side of the transporting path 48 so as to form the sheet feeding driving system 35 together with the sending roller 50.

The sheet feeding driving system 35 is driven synchronously by the feeding power transmission mechanism 36 shown in FIG. 2. The feeding power transmission mechanism 36 includes a timing belt 62 or the like for driving each of rollers synchronously.

Furthermore, the straight transporting path 48a thus formed downward includes a sheet discriminating unit 63 for discriminating sheets such as bills. The sheet discriminating unit 63 is formed of various types of sensors described later. Specifically, the sheet discriminating unit 63 has a configuration wherein each bill sequentially passes through a front/back discriminating sensor 64 for discriminating the front and the back of the bill, a line sensor 65 for discriminating the kind of the bill and for detecting whether the bill is whole or not, folded, or damaged, and a genuine/forged discriminating sensor 66 for discriminating whether the bill is genuine or counterfeit.

The front/back discriminating sensor 64 comprises a reflection light sensor for discriminating the patterns of the front and back of each bill.

While the front/back discriminating sensor 64 is included for improving discrimination performance of the bill discriminating/counting machine 10, the front/back discriminating sensor 64 is not indispensable to the present invention.

The line sensor 65 of the sheet discriminating unit 63 is a light transmission sensor serving as a bill-denomination discriminating sensor disposed so as to surround the straight transporting path 48a forming a straight transporting discriminating region across the straight transporting path 48a, and specifically, has a configuration wherein a light source array formed of LEDs or the like and a photo-receptor sensor array are disposed so as to be opposed to one another across the straight transporting path 48a with a suitable interval therebetween of several mm, and preferably with an interval therebetween of around 2 to 3 mm. The line sensor 65 performs line scanning processing for each transported bill along the longitudinal direction, whereby the entire surface of each bill is inspected.

On the other hand, the genuine/forged discriminating sensor 66 is formed of at least one of a magnetic sensor (MG sensor) and an ultraviolet sensor (UV sensor), wherein the magnetic sensor and the UV sensor are disposed on the straight transporting path 48a so as to cover a part of the bill passing therethrough along the width direction.

On the other hand, the counting-machine main unit 11 of the bill discriminating/counting machine 10 includes a reversal driving roller 70 at the lower portion on the rear side thereof so as to form the U-shaped curved transporting path 48b. The reversal driving roller 70 is formed of a large-diameter rubber roller so as to form the U-shaped curved transporting path 48b with a large radius of curvature. Specifically, the reversal driving roller 70 is formed with a diameter equal to or greater than ⅔ of the paper feeding pitch for feeding each bill, e.g., with a diameter of 50 mm, which is generally the same diameter as with the feeding roller 53.

The U-shaped curved transporting path 48b forms a curved transporting region and is formed of the reversal driving roller 70 and a U-shaped curved guide plate 71. The curved guide plate 71 is mounted so as to form the curved transporting path between the setting position and the releasing position for the bill so as to allow the bill to pass along, and the curved transporting path 48b includes a transporting driven rollers 72 and 73 at an upstream portion and a downstream portion thereof, which are pressed into contact with the reversal driving roller 70. The transporting driven rollers 72 and 73 serve as pinch rollers for providing transporting force to each bill.

The U-shaped curved transporting path 48b is formed with a length sufficient for keeping each bill during a period of time required for processing the detection signals from the sheet discriminating unit 63 so as to discriminate the bill, as well as with a large radius of curvature for preventing the jamming of the bills.

Furthermore, a crest-shaped or reverse-V-shaped transporting path 48c is formed downstream from the U-shaped curved transporting path 48b serving as a downstream transporting path. The crest-shaped transporting path 48c includes a gate timing sensor 75 on the entrance portion. Further, the gate timing sensor 75 is a light transmission sensor for detecting presence or absence of the bill passing through the entrance of the crest-shaped transporting path 48c.

The crest-shaped transporting path 48c is formed so as to extend from the rear side to the front side of the counting-machine main unit 11 of the bill discriminating/counting machine 10, on the lower portion thereof. Furthermore, a plurality of transporting driving rollers 77 through 79 are disposed along one surface of the crest-shaped transporting path 48c, e.g., along the upper surface thereof. The transporting driving rollers 77 and 79 are formed with the same roller diameter and are rotationally driven synchronously by a timing belt or the like.

Each of the driving rollers 77 through 79 is fixedly mounted on the counting-machine main unit 11 of the bill discriminating/counting machine 10, and on the other hand, transporting driven rollers 81 through 83 are disposed on the movable side thereof so as to face the corresponding transporting driving rollers 77 through 79. The transporting driven rollers 81 through 83 are elastically pressed into contact with the transporting driving rollers 77 through 79 so as to rotate in accordance with the rotation of the transporting driving rollers 77 through 79.

Furthermore, the upstream part of the crest-transporting path 48c serves as a reject discrimination transporting region formed of a stationary-side guide plate 84 and a movable-side guide plate 85, wherein each bill is transported while being supported between the transporting driving rollers 77 through 79 and the transporting driven rollers 81 through 83. The crest-shaped transporting path 48 includes a bill-detection sensor 86 on the downstream side thereof for detecting presence or absence of the bill passing therethrough.

The bill guided along the crest-shaped transporting path 48c is introduced to the stacker 21 by guide of a stacker impeller 90, whereby each bill is stacked on the stacker 21. A stacker sensor 91 detects whether or not there are any bills stacked on the stacker 21. The stacker 21 has a configuration in which about 300 to 1500 bills can be stored therein. The stacker sensor 91 comprises a photo-transmission sensor formed of a combination of a light-emission unit and a photo-receptor unit.

On the other hand, the crest-shaped transporting path 48c includes a switching gate 93 on the top thereof. The switching gate 93 is switched at a suitable timing according to sensor signals from the gate timing sensor 75. In a case of rejecting the bill discriminated by the sheet discriminating unit 63, the switching gate 93 detects the bill, which is to be rejected, passing therethrough by actions of the gate timing sensor 75, and is switched so as to lead the bill to a reject transporting path 48d at a suitable timing. Accordingly, the gate timing sensor 75 and the switching gate 93 are disposed with a distance therebetween sufficient for smoothly guiding the bill, which is to be rejected, detected by the gate timing sensor 75, to the reject transporting path 48d.

The reject transporting path 48d branching from the top of the crest-shaped transporting path 48c is formed so as to extend toward the pocket 20, and a plurality of transporting driving rollers 94 and 95 are provided along one surface of the reject transporting path 48d, e.g., the upper surface thereof. Furthermore, transporting driven rollers 96 and 97 are disposed in a manner of facing the corresponding transporting driving rollers 94 and 95 so as to be elastically pressed into contact therewith.

The reject transporting path 48d branching from the crest-shaped transporting path 48c is formed upward from the branching point so as to extend in the front direction with a positive inclination, and leads to the pocket 20. The reject transporting path 48d is formed of a stationary-side guide plate 98 and a movable-side guide plate 99. Further, a combination of the stationary-side guide plate 98 and the transporting driving rollers 94 and 95 forms a stationary-side unit, and on the other hand, a combination of the movable-side guide plate 99 and the transporting driven rollers 96 and 97 forms a movable-side unit which surfaces the stationary-side unit.

Furthermore, a bill-detection sensor 100 is disposed at a predetermined position on the reject transporting path 48d for detecting presence or absence of the rejected bill passing therethrough. The bill-detection sensor 100 is formed of a reflection light sensor. Specifically, the bill-detection sensor 100 is disposed at a position between the stationary-side transporting driving rollers 94 and 95.

Furthermore, the reject transporting path 48d includes a guide member 101 on the downstream portion thereof for smoothly guiding each bill, which is to be guided to the pocket 20, to the pocket receiver 22. Furthermore, an arrangement may be made wherein a patting roller is provided so as to extend in the tangential direction of the transporting driven roller 97 on the downstream side of the reject transporting path 48d for more smoothly guiding each bill to the pocket 20, and in this case, each bill is patted by the patting roller so as to be guided to the pocket 20. The pocket 20 has a configuration wherein around one hundred bills are stored therein, for example. A pocket sensor 102 is a transmitted light sensor formed of a combination of a light-emission unit and a light-receiving unit and detects whether or not there are any bills stacked on the pocket 20.

Thus, the bill discriminating/counting machine 10 includes the transporting path 48 within the counting-machine main unit 11 thereof for transporting each bill from the hopper 15 up to the stacker 21 as shown in FIG. 4. The transporting path 48 is formed of the straight transporting path 48a extending downward from the feeding roller 53, the U-shaped curved transporting path 48b formed at the lower portion on the rear side of the counting-machine main unit 11 following the straight transporting path 48a, and the crest-shaped transporting path 48c extending from the rear side of the counting-machine main unit 11 to the front side thereof following the curved transporting path 48b, in a zigzag form, and accordingly, the transporting path 48 is efficiently formed in a space within the counting-machine main unit 11, thereby forming a transporting path with a sufficient length. Thus, with the present embodiment, the transporting path 48 is formed in a zigzag form so as to be efficiently formed in a space within the counting-machine main unit 11, thereby enabling high-speed discriminating/counting processing for bills at a rate of about 1200 to 1500 sheets per minute as described later.

On the other hand, with the bill discriminating/counting machine 10, the switching gate 93 is formed generally at the middle portion of the counting-machine main unit 11 thereof, and the transporting path 48 is formed within the counting-machine main unit 11 from the hopper 15 up to the stacker 21 in a zigzag form with a radius of curvature as great as possible in order to prevent the sheets such as bills from jamming, whereby the transporting path 48 including the zigzag curved portions formed smoothly in the shape of an arc or a “U” is formed with a large radius of curvature over the entire path. This configuration enables the small-sized and compact bill discriminating/counting machine 10 with a sufficient length of the transporting path 48. Specifically, the configuration according to the present invention enables the desk-top bill discriminating/counting machine 10 with the height of 300 mm, the width of 330 mm, and the depth of 335 mm, for example.

While the bill discriminating/counting machine 10 has a mechanism for preventing jamming of bills on the transporting path 48 as much as possible, the bills which are to be subjected to sheet discriminating/counting processing are not restricted to brand-new ones, and rather, there are various paper conditions of bills such as soiled bills, folded bills, damaged bills, and the like. This may leads to jamming of bills which are to be subjected to the discriminating/counting processing on the transporting path 48 at the time of transporting the bills, resulting in a situation wherein subsequent transporting of bills cannot be performed.

In the event of jamming of bills on the transporting path 48, scram operations need to be performed so as to stop the operations of the bill discriminating/counting machine 10. In particular, in the event of jamming of bills, it is necessary to immediately stop the bill-feeding operations.

Accordingly, the bill discriminating/counting machine 10 has a configuration in which the sheet transporting system thereof is roughly divided into the sheet feeding driving system 35 and the sheet transporting driving system 37 as shown in FIG. 2 and FIG. 3, and the jamming on the transporting path is detected by various types of sensors. Upon detection of such jamming of the bills, the sheet feeding driving system 35 is immediately stopped so as to prevent following feeding of bills from the hopper 15.

The sheet feeding driving system 35 is driven by rotational driving force from the driving motor 39 through the feeding power transmission mechanism 36. In the event that jamming occurs on the transporting path 48, a brake drive on the circuit board 165 described later acts upon the brake device 45 (see FIG. 2) mounted to the driving motor 39 or the output shaft thereof, such as an electromagnetic brake, mechanical brake, or the like, according to signals due to detection of jamming, so as to immediately stop operations of the sheet feeding driving system 35. This mechanism prevents subsequent feeding of bills from the hopper 15 to the transporting path 48 at the time of jamming.

On the other hand, the sheet transporting driving system 37 is driven by rotational driving force from the driving motor 40 through the transporting power transmission mechanism 38. The transporting power transmission mechanism 38 primarily comprises a first transporting power transmission mechanism 104 for driving the transporting driving rollers 94 and 95 on the reject transporting path 48d, a second transporting power transmission system 105 driven through the first power transmission system 104, and a third transporting power transmission system 107 driven by the first transporting power transmission system 104 through a reducing mechanism 106. The second transporting power transmission system 105 is included for driving the reversal driving roller 70 and the transporting driving rollers 77 and 78 disposed along the crest-shaped transporting path 48c. Further, the driving force is transmitted from the first transporting power transmission system 104 to the second transporting power transmission system 105 through the shaft of the transporting driving roller 78 disposed along the crest-shaped transporting path 48c.

Furthermore, the driving force, which is transmitted from the transporting driving roller 78 disposed along the crest-shaped transporting path 48c driven by the first transporting power transmission system 104, is transmitted to the third transporting power transmission system 107 through the reducing mechanism 106. The third transporting power transmission system 107 has a configuration for rotationally driving the transporting driving roller 79 disposed on the exit side of the crest-shaped transporting path 48c and the stacker impeller 90. The transporting driving roller 79 disposed on the exit side of the crest-shaped transporting path 48c and the stacker impeller 90 are rotationally driven in directions reverse to each other, and accordingly, a reversible timing belt 108 is employed. In this case, the stacker impeller 90 is driven through the reversible timing belt 108 by the driving force reduced by the transporting driving roller 79. A suitable reduction ratio is set by selecting a desired gear ratio.

On the other hand, the power transmission is performed for the feeding power transmission mechanism 36 and the transporting power transmission mechanism 38 by means of the timing belt 62 (see FIG. 2). Further, another power transmission means may be employed, instead of the timing belt 62.

A part of the feeding power transmission mechanism 36, a part of the transporting power transmission mechanism 38, the second transporting power transmission system 105, the reducing mechanism 106 and the third transporting power transmission system 107 are disposed within a side space (machine chamber) 31 surrounded by the counting-machine main unit 11 and one of the side covers 13. On the other hand, the first transporting power transmission system 104 is disposed within the other side space 32 serving as a control camber. The aforementioned power transmission mechanisms and the power transmission systems constitute a sheet transporting device. Further, reference numeral 109 denotes a timing belt used for the second transporting power transmission system 105.

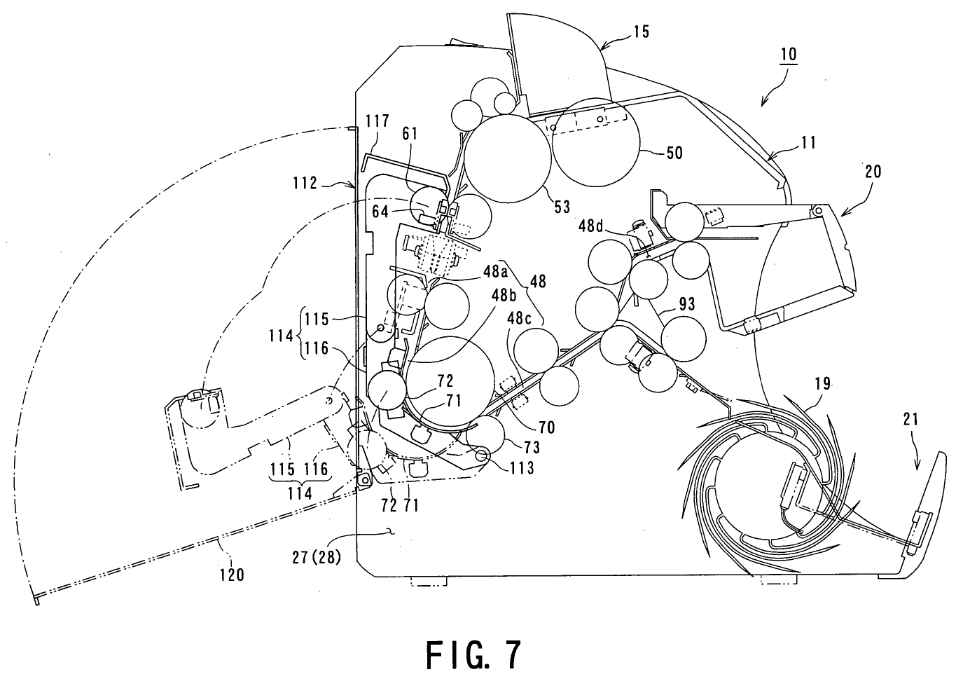

As shown in FIG. 7, the bill discriminating/counting machine 10 includes a transporting path opening mechanism for opening the transporting path 48. FIG. 7 shows a rear-side transporting path opening mechanism 112 for opening the straight transporting path 48a formed downward, serving as a part of the transporting path 48.

The rear-side transporting path opening mechanism 112 is a device for opening the straight transporting path 48a formed on the rear side of the counting-machine main unit 11 through a simple operation. The rear-side transporting path opening mechanism 112 includes a rear opening guide arm mechanism 114 turnably supported by a support shaft 113 disposed at the lower portion on the rear side of the counting-machine main unit 11. The opening guide arm mechanism 114 is formed of a pair of an upper guide arm 115 and a lower guide arm 116 having a frame structure, which are turnably connected one to another, and a handle lever 117 is disposed on the top of the upper guide arm 115.

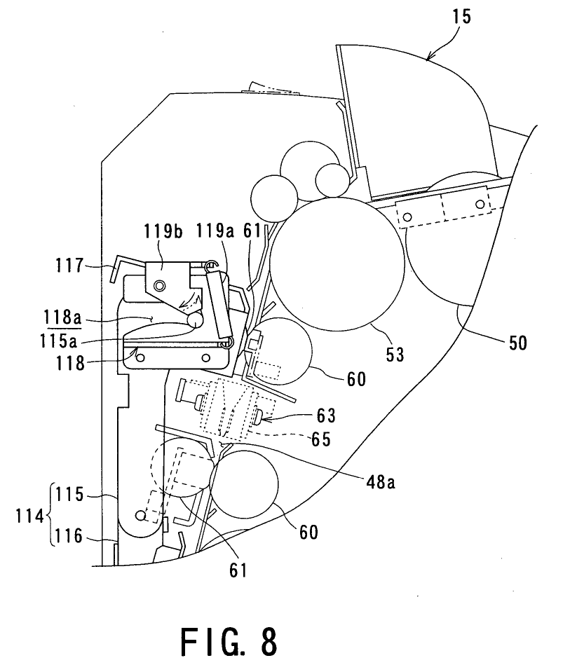

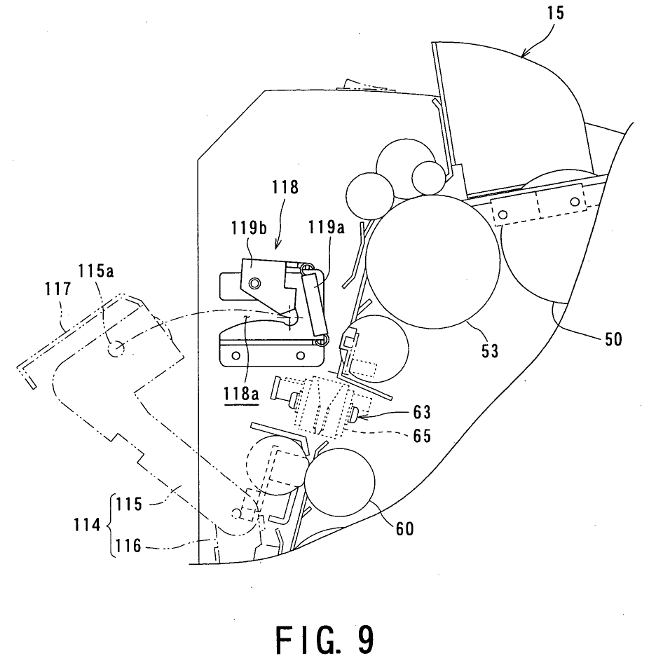

The upper guide arm 115 supports the driven roller 61 on the upper surface, a part of the reflection front/back discriminating sensor 64, and the movable-side guide plate 62b, and the upper guide arm 115 includes wrist pins 115a (see FIG. 8 and FIG. 9) protruding therefrom for detachably engaging to lock means 118 fixed to the main unit plates 27 and 28 of the counting-machine main unit 11 through a simple operation.

The rear-side transporting opening mechanism 112 is held at the setting position shown by solid lines in FIG. 7 by engaging the wrist pins 115a of the upper guide arm 115 to the lock means 118. On the other hand, the rear-side transporting opening mechanism 112 is easily opened by pulling the upper guide arm 115 forward while holding the handle lever 117 so as to apply upward force thereto. With the opened rear-side transporting path opening mechanism 112, the rear opening guide arm mechanism 114 is turned around the support shaft 113 in the counterclockwise direction in FIG. 7 and FIG. 9, and furthermore, the upper guide arm 115 is turned around the connecting portion between the upper guide arm 115 and the lower guide arm 116, whereby the straight transporting path 48a is completely opened.

On the other hand, the lower guide arm 116 having a frame structure includes the entrance-side transporting driven roller 72 and the U-shaped curved guide plate 71, and the U-shaped curved transporting path 48b is completely opened by turning the aforementioned lower guide arm 116 around the support shaft 113 in the counterclockwise direction in FIG. 7. Upon opening the U-shaped curved transporting path 48b, a user can easily remove jammed bills on the U-shaped curved transporting path 48b from the rear side of the counting-machine main unit 11.

Reference numeral 120 denotes a rear cover for covering the rear side of the counting-machine main unit 11. The rear cover 120 is turnably supported by hinges disposed at the lower portion of the rear side of the counting-machine main unit 11, and upon opening the rear cover 120, the rear-side transporting path opening mechanism 112 is exposed on the rear side thereof through an opening. Subsequently, upon pulling the handle lever 117 of the rear-side transporting path opening mechanism 112 forward, the rear-side transporting path opening mechanism 112 is opened from the lock position shown in FIG. 8, whereby the rear-side transporting path opening mechanism 112 is positioned at the opening position shown by dotted lines in FIG. 7 and FIG. 9.

Upon opening the rear-side transporting path opening mechanism 112, the straight transporting path 48a and the U-shaped curved transporting path 48b are opened on the rear side of the counting-machine main unit 11. Upon opening these components, the user can easily remove jammed bills on the straight transporting path 48a and the U-shaped curved transporting path 48b in a simple operation.

Following removal of the jammed bills from the straight transporting path 48a and the curved transporting path 48b of the transporting path 48, the user performs closing operations which are operations performed in the order reverse to that of the opening operations for the rear-side transporting path opening mechanism 112, whereby the rear-side transporting opening mechanism 112 is mounted at the setting position shown by solid lines in FIG. 7, thereby enabling following discriminating/counting processing for bills.

In this case, the transporting path 48 formed from the hopper 15 is curved through the feeding roller 53, and continues to the straight transporting path 48a. The straight transporting path 48a leads from the upper portion to the lower portion of the rear side of the counting-machine main unit 11 and is positioned near the rear cover 120, and accordingly, upon opening the rear-side transporting path opening mechanism 112, the straight transporting path 48a and the U-shaped curved transporting path 48b are widely opened.

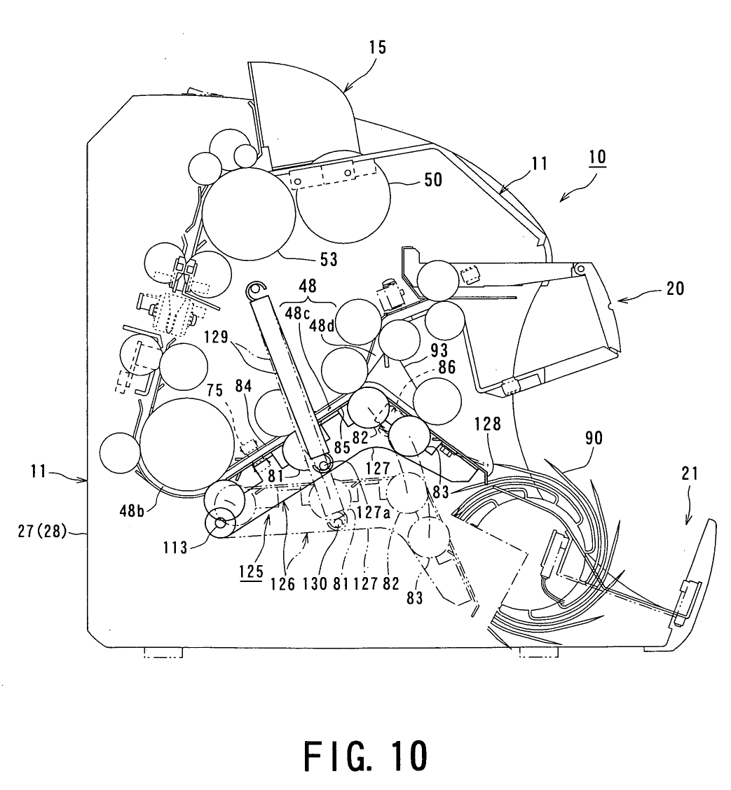

Furthermore, the bill discriminating/counting machine 10 includes a crest-shaped transporting path opening mechanism 125 for opening the crest-shaped transporting path 48c serving as a downstream transporting path within the counting-machine main unit 11 as shown in FIG. 10. The crest-shaped transporting path 48c extends from the exit side of the U-shaped curved transporting path 48b formed at the lower portion on the rear side of the counting-machine main unit 11 in the forward direction of thereof and leads to the stacker 21 through the stacker impeller 90.

The crest-shaped transporting path 48c is composed of the upper stationary-side guide plate 84 and the lower movable-side guide plate 85 in the shape of a crest or a reversed “V”. The movable-side guide plate 85 is mounted to a front opening guide arm mechanism 126 turnably supported by the support shaft 113. The front opening guide arm mechanism 126 includes a movable guide arm 127 having a frame structure in the shape of a smooth crest or reversed “V” as viewed from the side thereof.

The movable guide arm 127 is turnably supported by the same support shaft 113 as with the rear-side supporting path opening mechanism 112 and is held at the setting position thereof shown by solid lines in the drawing by force of a spring, not shown, in normal situations. The movable guide arm 127 having a frame structure includes wrist pins 130, which pass through slots formed on the main unit plates 27 and 28 with the greater diameter parallel to the vertical direction, protruding therefrom, and the wrist pins 130 are supported by an upward force of springs 129, whereby the movable guide arm 127 is supported.

The movable guide arm 127 of the crest-shaped transporting path opening mechanism 125 includes the crest-shaped movable-side guide plate 85, the transporting driven rollers 81, 82, and 83, forming a roller array, the gate timing sensor 75, and the reflection light sensor 86. The free end of the movable guide arm 127 includes a handle lever 128 extending therefrom. The handle lever 128 extends forward between the stacker impellers 90 composed of a pair of stacker impeller sub-units, whereby the user can perform operations thereof from the front side.

The bill discriminating/counting machine 10 has a configuration wherein the user can press down on the handle lever 128 of the crest-shaped transporting opening mechanism 125, disposed between the pair of the stacker impeller sub-units forming the stacker impellers 90, against the spring force of the springs 129. Upon the user pressing down on the handle lever 128, the opening guide arm 126 is turned around the support shaft 113, whereby the crest-shaped transporting path 48c is completely opened forward as shown by chain lines in the drawing.

Upon opening the crest-shaped transporting path 48c on the front side, the user can remove jammed bills on the crest-shaped transporting path 48c. Following removal of the jammed bills from the front side, upon releasing the handle lever 128, the front opening guide arm mechanism 126 is automatically returned to the setting position shown by solid lines in the drawing by the spring force of the spring 129.

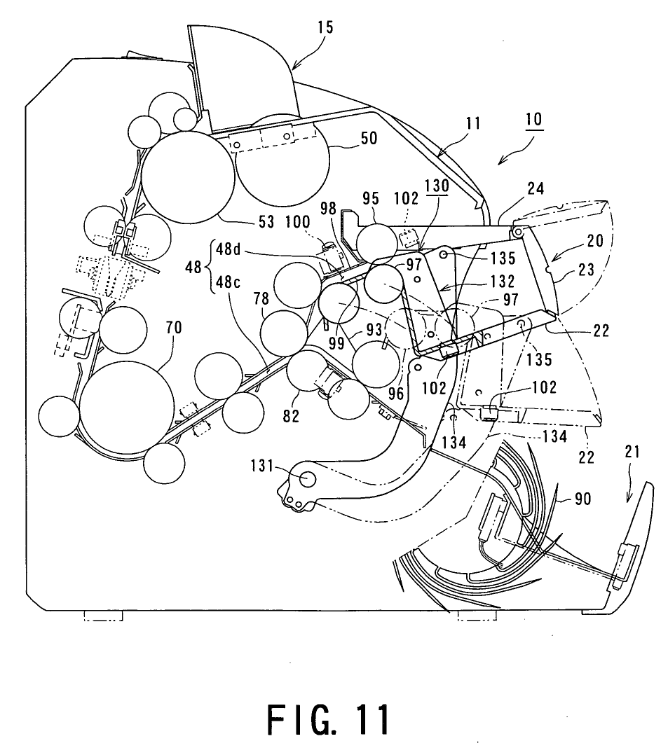

Furthermore, the bill discriminating/counting machine 10 includes a reject transporting path opening mechanism 130 for opening the reject transporting path 48d as shown in FIG. 11.

The reject transporting opening mechanism 130 includes a reject opening guide arm mechanism 132 which can be turned around a support shaft 131. The support shaft 131 is provided at the lower portion on the middle side of the counting-machine main unit 11, and an L-shaped guide arm 134 is turnably supported by the support shaft 131. Thus, the guide arm 134 can be turned between the setting position shown by solid lines and the opening position shown by chained lines as viewed from the side thereof in FIG. 11.

The guide arm 134 of the reject opening guide arm mechanism 132 is formed in the shape of an arc with a great length and includes the pocket 20 on the free end thereof. Specifically, the curved guide arm 134 composed of a pair of guide arm sub-units includes the pocket receiver 22 at the upper portion thereof for the pocket 20. On the other hand, the transporting driven rollers 96 and 97 disposed along the reject transporting path 48d are rotatably supported by the curved guide arm 134. Furthermore, the movable-side guide plate 99 is mounted to the free end of the guide arm 134. The movable-side guide plate 99 is mounted so as to surface the stationary-side guide plate 98 on the upper side, thus the reject transporting path 48d being formed between both the guide plates 98 and 99.

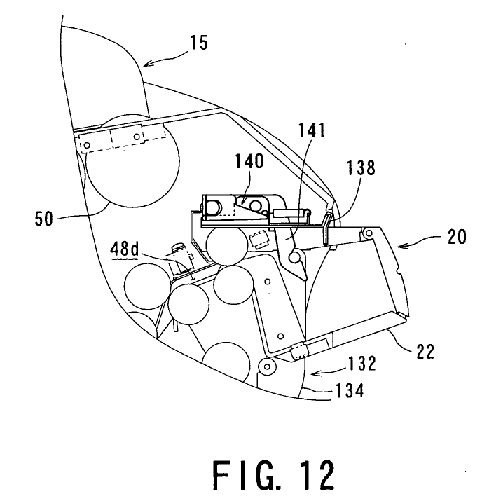

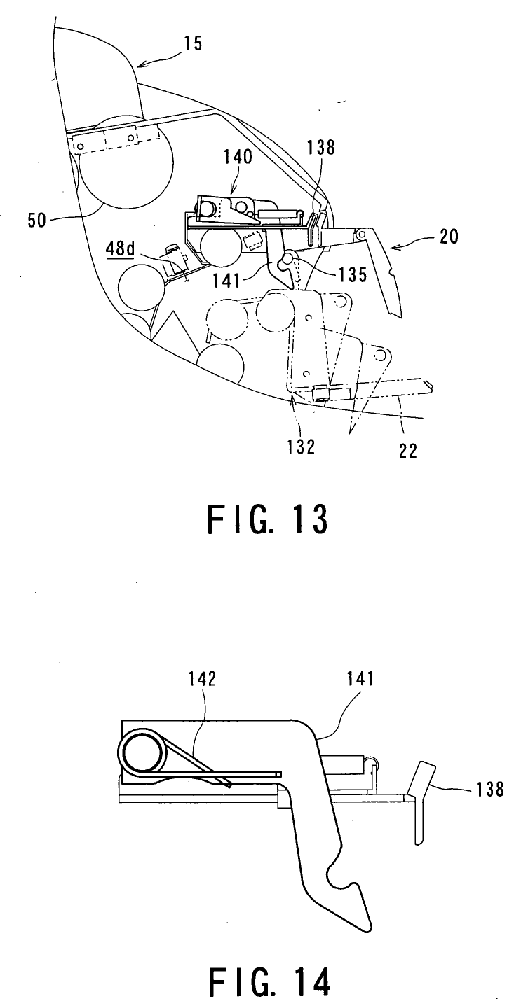

The reject opening guide arm mechanism 132 has a configuration in which a bridge pin 135 is disposed so as to form a bridge serving as an engaging member between the free ends of the pair of the guide arm sub-units forming the guide arm 134 as shown in FIG. 12 and FIG. 13, and the bridge pin 135 is held and locked with an engaging hook 141 disposed on the counting-machine main unit 11, whereby the reject opening guide arm mechanism 132 is held at the setting position shown by solid lines.

In a case of opening the reject opening guide arm mechanism 132, the user presses down on an operation button 138 disposed on the upper surface of the pocket 20 as shown in FIG. 11 through FIG. 13 so as to turn the engaging hook 141 through the cam mechanism 140, so that the bridge pin 135 is disengaged from the engaging hook 141. Upon disengaging the bridge pin 135, the lock mechanism of the reject opening guide arm mechanism 132 is disengaged and is then turned in the clockwise direction in FIG. 11 due to the weight thereof to thereby position the reject opening guide arm mechanism 132 at the reject transporting opening position shown by chain lines shown in FIG. 13.

Upon opening the reject opening guide arm mechanism 132, the pocket receiver 22 forming the lower portion of the pocket 20 is moved downward so that the pocket 20 disposed on the front surface of the bill discriminating/counting machine 10 is completely opened downward. That is to say, the reject opening guide arm mechanism 132 serves as a mechanism for opening the pocket 20 downward, as well as opening the reject transporting path 48d.

Upon the user performing operations for opening the reject opening guide arm mechanism 132, the reject transporting path 48d is completely opened forward through the opened pocket 20, and thus, the user can remove jammed bills on the reject transporting path 48d through the opening.

In this case, the reject opening guide arm mechanism 132 of the reject transporting path opening mechanism 130 includes the guide arm 134 with a great arm length and is turned around the support shaft disposed at the lower portion of the counting-machine main unit 11, and thus, the opening action of the reject opening guide arm mechanism 132 enables the user to easily remove the jammed bills on the reject transporting path 48d.

In a case of returning the reject transporting path 48d of the reject transporting path opening mechanism 130 to the normal state, the user pushes up the pocket receiver 22 of the pocket 20 so as to be positioned from the opening position shown by chain lines to the setting position shown by solid lines in FIG. 11. Upon the pocket receiver 22 reaching the position shown by the solid lines, the bridge pin 135 disposed at the tip of the guide arm 134 engages with the engaging hook 141, whereby the reject transporting path 48d is held at the setting position. The bridge pin 135 engages with the engaging hook 141 by spring force of the spring 142 in normal situations as shown in FIG. 14.

As described above, the bill discriminating/counting machine 10 includes the rear-side transporting path opening mechanism 112, the crest-shaped transporting path opening mechanism 125, and the reject transporting path opening mechanism 130, wherein the user can perform opening operations separately using the transporting path opening mechanisms 112, 125, and 130, as shown in FIG. 7 through FIG. 13.

The rear-side transporting opening mechanism 112 enables complete opening of the straight transporting path 48d and the U-shaped curved transporting path 48b on the rear side. On the other hand, the crest-shaped opening mechanism 125 enables complete opening of the crest-shaped transporting path 48c on the front side, and the reject transporting path opening mechanism 130 enables complete opening of the reject transporting path 48d on the front side, thereby enabling the user to easily remove jammed bills on the transporting path 48 in simple operation.

Furthermore, the reject transporting path opening mechanism 130 also serves as a pocket opening mechanism in which, when the user performs the opening operations of the reject transporting path opening mechanism 130, the pocket receiver 22 disposed at the lower portion of the pocket 20 is moved downward so as to be completely opened. Thus, the user can remove the jammed bills on the reject transporting path 48d through the opening formed around the pocket 20.

As shown in FIG. 4 through FIG. 13, the bill discriminating/counting machine 10 has a configuration in which the transporting path 48 included in the counting-machine main unit 11 comprises a driving unit formed on one side and a driven unit formed of the other side.

With the bill discriminating/counting machine 10, the driving unit includes the sending roller 50, the feeding roller 53, the transporting driving rollers 60 and 60 disposed along the straight transporting path 48a, the reversal driving roller 70, the transporting driving rollers 77 and 78 disposed along the crest-shaped transporting path 48c, and the transporting driving rollers 94 and 95 disposed along the reject transporting path 48d, disposed along the inner side of the transporting path 48 so as to be positioned on the middle side of the counting-machine main unit 11 in a concentrated manner. This mechanism enables the efficient layout of the power transmission system for driving the rollers forming the driving unit.

On the other hand, the driven unit of the bill discriminating/counting machine 10 has a configuration in which each of the rollers is arrayed and disposed along the outside of the transporting path 48, thereby facilitating operations of the transporting path opening mechanisms 112, 125, and 130.

The bill discriminating/counting machine 10 has a configuration in which the rollers forming the driving unit and the rollers forming the driven unit are arrayed along the transporting path 48 extending from the hopper 15 to the stacker 21 or the pocket 20 so as to form corresponding roller arrays. Further, the rollers forming the driving unit and the rollers forming the driven unit are arrayed with a smaller interval than the length of the shorter side of each sheet such as a bill, i.e., the feeding pitch for bills.

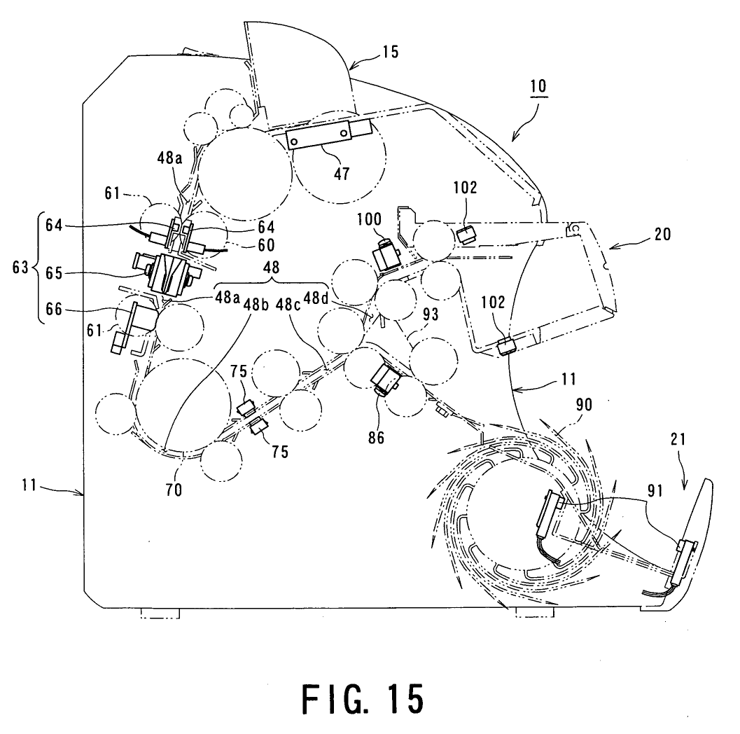

FIG. 15 is a diagram which shows the layout of the transporting path 48 and the various kinds of sensors disposed along the transporting path 48 formed in the bill discriminating/counting machine 10.

The hopper 15 for supplying sheets such as bills includes the hopper sensor 47 for detecting whether or not there are any bills stacked on the bottom thereof. The hopper sensor 47 comprises a reflection light sensor, for example.

On the other hand, the straight transporting path 48a of the transporting path 48 includes a sheet discriminating unit 63. The sheet discriminating unit 63 includes the front/back discriminating sensor 64, the line sensor 65 serving as discriminating sensor for discriminating the kind of each bill, discriminating whether the bill is whole or damaged, and discriminating whether or not the bill is folded, and the sheet discriminating unit 63 also includes the genuine/forged discriminating sensor 66 for discriminating whether the bill is genuine or forged, in that order from the upstream side to the downstream side.

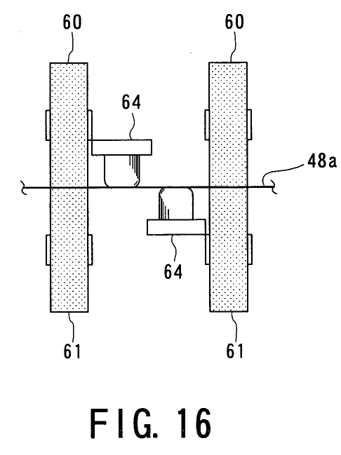

The front/back discriminating sensor 64 comprises a reflection light sensor, for example, and a pair of the front/back discriminating sensors 64 are disposed on both sides across the straight transporting path 48a in order to discriminate the front and the back of each bill. Although each front/back discriminating sensor 64 is not dispensable to the present invention, the front/back discriminating sensors 64 are included for discriminating the front and back of each bill. With the front/back discriminating sensor 64 formed of a reflection light sensor, each sensor is preferably disposed such that the surface passing over the surface of the sensor generally matches the surface passing over the surface of each roller for improving the performance of the sensor. However, with such a configuration in which the front/back discriminating sensors 64 and 64 forming a pair are disposed so as to be opposed to each other, the jamming may readily occur. Accordingly, the front/back discriminating sensors 64 and 64 which are light sensors disposed on both sides of the transporting path 48 are disposed at positions distanced one from another in the transporting width direction as shown in FIG. 16. The reason is that such a mechanism effectively prevent the jamming of the bills.

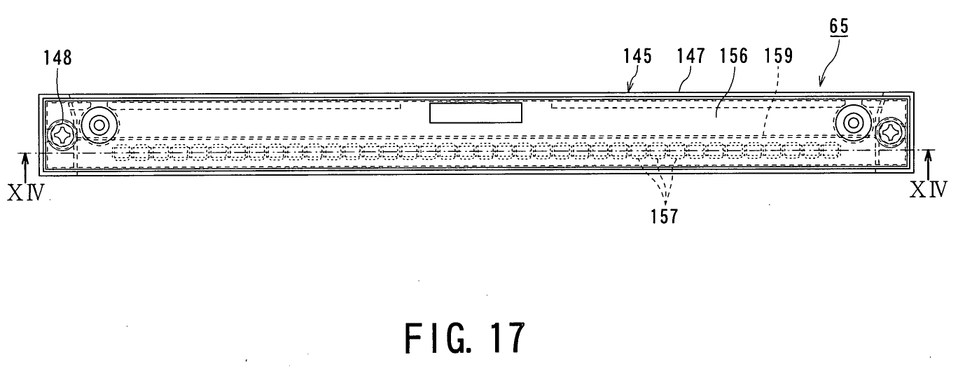

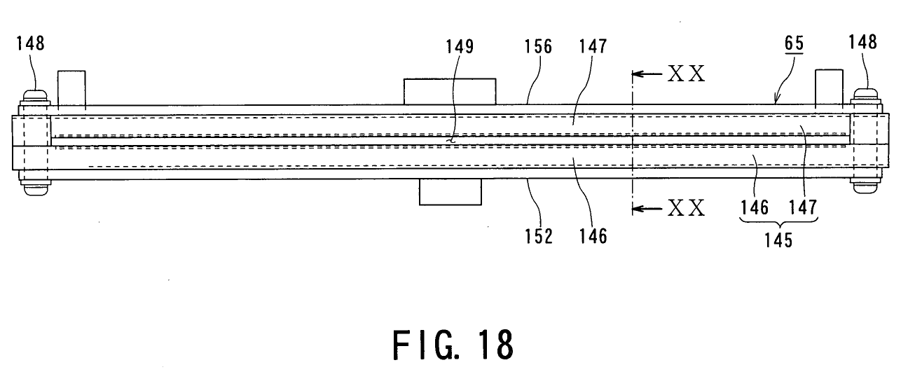

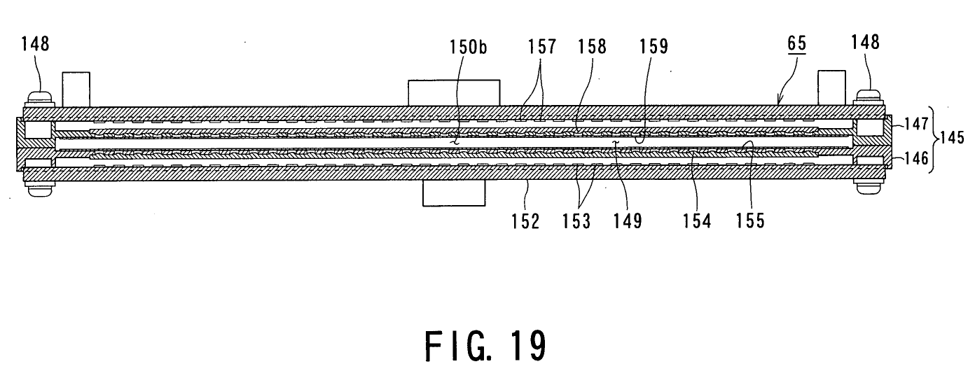

On the other hand, as shown in FIG. 17 through FIG. 20, the line sensor 65 is disposed at a position between an upstream roller pair including the upstream driving transporting roller 60 and driven transporting roller 61, and a downstream roller pair including the downstream driving transporting roller 60 and driven transporting roller 61. The line sensor 65 is disposed along the width direction of the transporting path across the transporting path 48, thereby enabling scanning of the entire surface of each bill passing through the straight transporting path 48a, as described later.

On the other hand, as shown in FIG. 21, the genuine/forged discriminating sensor 66 is included for determining whether each bill is genuine or forged and is formed of a magnet sensor (MG sensor) and a UV sensor. While the magnet sensor and the UV sensor are disposed along the width direction of the transporting path 48, the combination of the magnet sensor and the UV sensor is not indispensable to the present invention, and rather, an arrangement which includes either of these sensors may be made.

Furthermore, as shown in FIG. 15, the gate timing sensor 75 is disposed at a position downstream from the reversal driving roller 70. The gate timing sensor 75 is a transmitted light sensor for detecting presence or absence of a bill passing therethrough and for generating gate-action instructions to the switching gate 93. The gate timing sensor 75 is preferably disposed at a position as close to the reversal driving roller 70 as possible so as to ensure a sufficient distance between the gate timing sensor 75 and the switching gate 93. The reason is that a sufficient period of time is required for switching the switching gate 93 according to the gate-action instruction signals received from the gate timing sensor 75. Accordingly, the gate timing sensor 75 is disposed on the entrance side of the crest-shaped transporting path 48c.

The exit-side region of the crest-shaped transporting path 48c includes the bill-detection sensor 86 for detecting the bill which is to enter the stacker. The bill-detection sensor 86 for detecting a bill which is to enter the stacker is disposed at a position downstream from the switching gate 93 and is formed of a reflection light sensor, for example.

On the other hand, each bill transported through the crest-shaped transporting path 48c is guided to the stacker impeller 90, following which the bill is transported to the stacker 21 and is then stacked on the stacker 21. The stacker 21 has a configuration so that about 300 to 1500 bills can be stored therein. The stacker 21 includes the stacker sensor 91 formed of a transmitted light sensor for detecting whether or not there are any bills stacked on the stacker 21.

On the other hand, the reject transporting path 48d branches from the top of the crest-shaped transporting path 48c, and the bill-detection sensor 100 is disposed on the reject transporting path 48d for detecting a bill which is to enter the pocket. The bill-detection sensor 100 for detecting the bill which is to enter the pocket is disposed at a position downstream from the switching gate 93, and is formed of a reflection light sensor, so that the detection sensor 100 detects whether or not there are any bills which are transported to the pocket 20.

Each bill which is transported to the pocket 20 is introduced to the pocket 20 by guide of the guide member 101 and is stacked within the pocket 20. The pocket 20 has a capacity for storing about 100 to 300 bills. The pocket 20 includes the pocket sensor 102 for detecting whether or not there are any bills stacked thereon. The pocket sensor 102 is formed of a transmitted light sensor.

As described above, with the bill discriminating/counting machine 10, while various types of sensors selected as necessary are arrayed along the transporting path 48 so as to form a sensor group, and a pair of the front/back discriminating sensors 64 forming the sheet discriminating unit 63 are disposed on both sides across the straight transporting path 48a as shown in FIG. 16. The front/back discriminating sensors 64 forming a pair are disposed at positions close to the transporting path 48a and distanced one from another in the width direction of the transporting path 48a with a distance of about 10 mm therebetween, for example. Each front/back discriminating sensor 64 detects the reflected light in order to discriminate the front and the back of a bill passing through the straight transporting path 48a, i.e., the front/back discriminating sensor 64 discriminates the pattern of the front and the back of the bill based upon the difference in the reflected light amount so as to discriminate whether the front/back discriminating sensor 64 faces the front or the back of the bill.

On the other hand, the line sensor 65 forming the sheet discriminating unit 63 has a configuration as shown in FIG. 17 through FIG. 20. The line sensor 65 has a detection width sufficient for scanning the entire surface of the bill in order to facilitate handling of the bills having various kinds of patterns and sizes of various countries in the world. Although FIG. 17 through FIG. 20 show the line sensor 65 for being included within the bill discriminating/counting machine 10, the line sensor 65 may be included within an automatic ticket gate machine or a vending machine, serving as a discriminating unit for discriminating bills.

The line sensor 65 is disposed at a position between the upstream roller pair formed of the upstream transporting driving roller 60 and the transporting driven roller 61, and the downstream roller pair formed of the downstream transporting driving roller 60 and the transporting driven roller 61, across the transporting path. As shown in FIG. 17 through FIG. 19, the line sensor 65 includes a sensor main unit 145 formed in the shape of a long and narrow block. The sensor main unit 145 is composed of two separate members of a light-emission sensor member 146 and a photo-receptor sensor member 147, and has a configuration in which both the sensor members 146 and 147 are disposed so as to face to each other and connected with fixing means 148 so as to form a single unit.

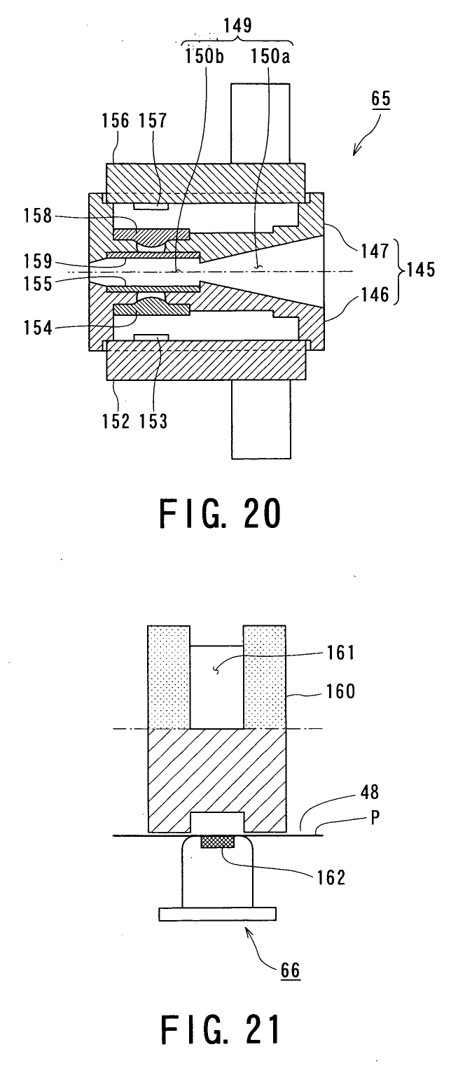

With the sensor main unit 145, the gap between both the sensor members 146 and 147 serves as a guide path 149 for allowing sheets such as bills to pass therethrough, which forms a part of the straight transporting path 48a. As shown in FIG. 20, the guide path 149 is formed of a tapered guide path 150a on the upstream side and a parallel slit guide path 150b on the downstream side. The tapered guide path 150a is formed to be tapered with a width thereof gradually reduced along the direction from the upstream side to the downstream side, and then, smoothly leads to the slit guide path 150b. The slit guide path 150b is formed with a gap of several mm, specifically, with a gap of about 2 to 3 mm, for example, and preferably, with a gap of about 2 mm.

The light-emission sensor member 146 forming the sensor main unit 145 includes a light-emission board 152 on the rear surface thereof which includes light-emission devices 153 such as infrared LEDs, laser light sources, or the like. A number of the light-emission devices 153, e.g., thirty-eight light-emission devices 153 are arrayed with a predetermined pitch, e.g., with a pitch of 5 mm in the longitudinal direction thereof. Each light-emission device 153 is a spot light source. Further, each light-emission device 153 is not restricted to a spot light-emission device, and rather, each light-emission device 153 may be formed in the shape of a line.

The light-emission sensor member 146 includes a plate-shaped lens member 154 for converting the light emitted from the spot light emission device 153 into parallel light. The lens member 154 has a configuration in which a number of lenses, e.g., thirty-eight lenses, are arrayed with a predetermined pitch so as to integrally form a lens group. Each lens of the lens member 154 is disposed so as to oppose to the corresponding spot light-emission device 153. The lens member 154 is covered with a transparent cover plate 155 such as a cover glass or the like, and the cover plate 155 is exposed so as to oppose to the slit guide path 150b.

On the other hand, the photo-receptor sensor member 147 facing the light-emission sensor member 146 includes a light-receiving board 156 on which photo-receptors 157 such as photodiodes, CCDs, or the like, are arrayed. The light-receiving sensor member 147 including the light-receiving board 156 includes a lens member 158 and a transparent cover plate 159, as with the lens member 154 and the cover plate 155 of the light-emission sensor member 146, respectively. The transparent cover plate 159 is disposed so as to face the cover plate 155 of the light-emission sensor member 146, and the gap between both the cover plates 155 and 159 serves as a slit guide path 150b. Thus, the slit guide path 150b serves as a region for inspecting and detecting each bill guided to the guide path 149.

On the other hand, the lens member 158 of the light-receiving sensor member 147 scans and concentrates the transmitted light, which has been emitted from each light-emission device 153 of the light-emission sensor member 158, and has been converted into parallel light by the lens member 154, onto the device surface of the photo-receptor 157 so as to allow each photo-receptor 157 to receive sufficient transmitted light. The photo-receptors 157 are arrayed in the shape of a line so as to oppose to the corresponding light-emission devices 153 in the same way as therewith, and these light-emission devices 153 and photo-receptors 157 form a light-emission unit and a light-receiving unit, respectively, whereby a transmitted light detector is completed.

That is to say, the line sensor 65 is formed of a transmitted light detector and has a detecting width sufficient for scanning the entire surface of any one of bills of various countries in the world, having various patterns and sizes.

At the time of scanning the entire surface of each bill with the line sensor 65, scanning is preferably performed with a distance between the line sensor 65 and the bill as small as possible in order to facilitate the detection of the change in the light intensity and to obtain stable scan data. Accordingly, the slit guide path 159b of the guide path 149 is preferably formed with a height (gap) as small as possible, and in this case, each bill guided to the small gap is scanned while being in contact with the sensor, or facing the sensor with a narrow gap, thus obtaining stable scan data.

However, in reality, there are various paper conditions such as creased bills, bills with folded corners, soiled bills, brand-new bills and the like, and accordingly, the slit guide path 150 having an excessive narrow gap may cause jamming of bills on the sensor. Accordingly, an arrangement including the guide path 149 having a narrow gap needs to involve a jamming-preventing mechanism for bills. An ideal arrangement preferably has the guide path 149 with the same height (gap) as with the height (gap) of the straight transporting path 48a.

On the other hand, in general, in a case of scanning a bill by using the transmitted light detector with an excessive great gap between the light-emission unit and the light-receiving unit, the intensity of the transmitted light changes due to irregularities in a gap between the bill and the light-receiving unit when the bill passes through the guide path 149, leading to difficulty in obtaining stable scan data required for discriminating the bill.

Furthermore, with the present embodiment, the entire surface of each of the bills is scanned by repeating line scanning using the line sensor 65 shown in FIG. 17 through FIG. 20, and accordingly, the slit guide path 150a serving as a detecting/inspecting region cannot include sending rollers such as rubber rollers or the like. That is to say, it is difficult to provide means within the line sensor 65 for preventing deviation of each bill in the scanning process.

In consideration of the above problems, the line sensor 65 shown in FIG. 17 through FIG. 20 have a configuration in which the diffused light from each light-emitted device 153 is converted into parallel light by the corresponding lens of the lens member 154, which is then cast onto a bill, so as to prevent the change in the incident light (cast light) due to the difference in the distance between the bill and the sensor. On the other hand, the light-receiving unit formed of photo-receptors 157 includes the lens member 158, as well, such that the parallel light is concentrated onto the corresponding photo-receptor 157 by the corresponding lens of the lens member 158, thereby preventing irregularities in output signals due to the change in the intensity of the received light even in a case of employing the photo-receptor 158 with a small chip size.

On the other hand, the genuine/forged discriminating sensor 66 disposed at a position downstream from the line sensor 65 is composed of an magnetic sensor, for example, and a pair of the genuine/forged discriminating sensors 66 are formed in the width direction of the transporting path 48, for example. As shown in FIG. 21, each magnetic sensor is disposed to face a sensor roller 160 such that a sensor head 162 of the magnetic sensor is disposed within a groove 161 formed on the sensor roller 160. The sensor head 162 is disposed to face the sensor roller 160 so as to be positioned as close as possible to a bill P which is to be discriminated and guided to the transporting path 48 so as to enable the sensor head 162 to contact with the bill P. Further, a UV sensor using ultraviolet light may be employed instead of the magnetic sensor, and furthermore, a combination of the UV sensor and the magnetic sensor may be employed, and in this case, the UV sensor may be disposed at a position between the magnetic sensors forming a pair, or the UV sensor may be disposed at a position downstream from the magnetic sensors.

The detection signals thus detected by the front/back discriminating sensor 64, the line sensor 65 and the genuine/forged discriminating sensor 66, are transmitted to an computation control system 166 on the circuit board 165 so as to be subjected to the computation processing as shown in FIG. 22. The circuit board 165 is disposed within the side space 32 serving as a control chamber shown in FIG. 3, for example.

The circuit board 165 primarily comprises the computation control system 166, a power supply system 167 for supplying voltage, sensor processing system 168 and a power control system 169 as shown in FIG. 22.

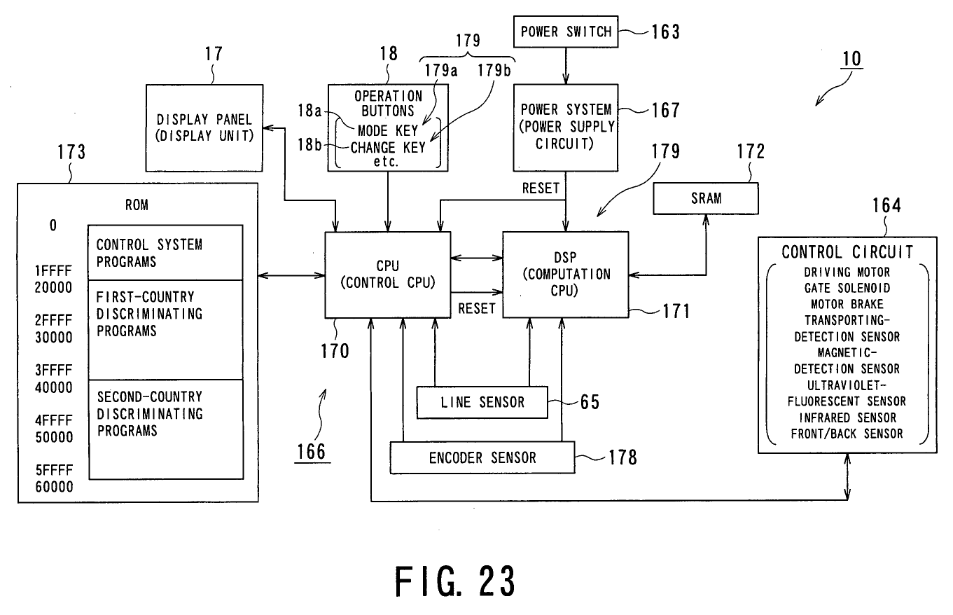

The computation control system 166 includes two CPUs of a control CPU 170 connected to the operation buttons 18 (see FIG. 1) and a computation CPU 171 such as a digital signal processor (DSP) or the like connected to the control CPU 170. The computation CPU 171 bears the load of computation processing, and the control CPU 170 is electrically connected to the driving motor 39 of the sheet feeding driving system 35, the driving motor 40 of the sheet transporting driving system 37, a gate solenoid, not shown, for controlling the switching gate 93 for switching destination of each bill, a motor brake, not shown, for stopping the feeding driving motor 39, and the control circuit 164 (see FIG. 23) for performing rapid control of each sensor. The aforementioned configuration allows the control CPU 170 to control and drive the control circuit 164, thereby enabling rapid control processing for operating the mechanisms of the bill discriminating/counting machine 10.

While the control CPU 170 includes program ROM 173 for storing control programs, first-country discriminating programs, second-country discriminating programs, and computation programs, the control CPU 170 performs control processing according to the control programs from the program ROM 173, drives and controls the control circuit 164, and operates and controls motor drivers 174 and 174, a brake driver 175, a gate driver 176, and the like, of the power control system 169. One of the motor drivers 174 and 174 controls start/stop and braking of the feeding driving motor 39 and the other controls start/stop and braking of the transporting driving motor 39.

On the other hand, the brake driver 175 is included for driving and controlling a motor brake such as a mechanical brake, electromagnetic brake, or the like, for stopping the feeding driving motor 39 in an emergency, and the gate driver 176 is included for operating and controlling the gate solenoid for controlling the switching gate 93.

Further, in the power control system 169, reference numeral 177 denotes a current control resistance.

Furthermore, the bill discriminating/counting machine 10 has a configuration in which the control CPU 170 and the computation CPU 171 can be connected to an external power supply (not shown) through a power system 167 formed of multiple power supply units serving as power circuits, and a power switch 163, and upon turning on the power switch 163, an external voltage (AC voltage) of 100 to 240 V is applied to the power system 167, for example. The AC voltage is converted into DC voltages by a power supply circuit of the power system 167, and specifically, the AC voltage is converted into a signal system operating voltage of 5 V and a power system driving voltage of 24 V, for example.

The control CPU 170 and the computation CPU 171 are connected to an encoder 178 (see FIG. 2) for generating timing signals for transporting operations of the entire bill discriminating/counting machine 10, as well as being connected to the sensors 64, 65, and 66 of the sheet discriminating unit 63 (see FIG. 15). The encoder 178 detects slits formed on a pulse disk so as to generate transporting timing signals for the entire machine.

The control CPU 170 reads out discriminating programs including data with regard to bills which are to be discriminated for the DSP (computation CPU) 171 from the program ROM 173, transmits the programs to SRAM 172, and stores the programs therein, as well as starting control of the bill discriminating/counting machine 10.

The DSP 171 performs computation processing for scan information (scan data) from the line sensor 65 based upon the discriminating programs and the information with regard to bills which are to be discriminated, included therein, which have been transmitted to and stored in the SRAM 172, and discriminating results for the bill are transmitted to the control CPU 170. The control CPU 170 performs control of control circuits of the sensors, the driving motors, the gate solenoid, the motor brake, and the like, based upon the discriminating results, thereby enabling discriminating/counting processing for each bill which is to be discriminated, which has been transported one by one by the feeding roller 53.

While the computation CPU 171 is connected to the control CPU 170 so as to serve as a part of the control CPU 170 for performing computation processing, the computation CPU 171 includes the SRAM (STATIC RAM) 172 electrically connected thereto. The programs are transmitted from the program ROM 173 to the SRAM 172 through the circuit of the computation CPU 171 by the control CPU 171 and are stored in the SRAM 172 for operating the computation CPU 171.

The program ROM 173 stores the control system programs, the computation programs, the first-country discriminating programs, and the second-country discriminating programs, with corresponding addresses. The first-country discriminating programs are used for discriminating US Dollar bills, for example, and on the other hand, the second-country discriminating programs are used for discriminating Japanese Yen bills.

In a case of employing the program ROM 173 with a sufficient capacity, the program ROM 173 may stores discriminating programs for a number of countries such as a third-country discriminating programs, and the like. The third-country discriminating programs are used for discriminating European euro bills, or Chinese Yuan bills, for example.

In the drawing, the numerals shown on the left side of the program ROM 173 denote storage addressing numbers, wherein the program ROM 173 stores the control system programs with addressing numbers of 0 to 1FFFF, the first-country discriminating programs with addressing numbers of 20000 to 2FFFF, and with addressing numbers of 30000 to 3FFFF.

Furthermore, the bill discriminating/counting machine 10 includes discrimination-object selecting means 179 for selecting discriminating programs in order to discriminate sheets such as bills of a predetermined country which are to be discriminated. The discrimination-object selecting means 179 form a part of the computation control system 167 and the power control system 169 shown in FIG. 22, and includes the control CPU 170 and the computation CPU 171.

Specifically, as shown in FIG. 23, the discrimination-object selecting means 179 includes: the operation buttons (operation keys) 18; the CPU 170 connected to the operation buttons 18; the program ROM 173 connected to the control CPU 170 for storing discriminating programs for bills of multiple countries or regions which are to be discriminated; the computation CPU 171 connected to the control CPU 170 for performing discriminating computation processing for bills which are to be discriminated; and the SRAM 172 in which the discriminating programs with regard to bills of the countries, which are to be discriminated, stored in the program ROM 173, are read out at the time of start of the control CPU 170, and in which the programs are stored through the circuit of the computation CPU 171. In this case, upon start of the control CPU 170, the discriminating programs for bills of countries which are to be discriminated are stored in the SRAM 172, and the computation CPU 171 reads out the discriminating programs stored in the SRAM 172 according to instructions from the control CPU 170 and performs the comparison processing for sensor signals received from the line sensor 65 synchronously with timing signals corresponding to each bill which is to be discriminated, received from the encoder sensor 178, in accordance with the discriminating programs, thereby performing discriminating computation processing such as discrimination of the kind of the bill which is to be discriminated, discrimination whether the bill is whole or damaged, discrimination whether or not the bill is folded, and the like.

The discrimination-object selecting means 179 include activation time discrimination-object selecting means 179a for selecting discriminating programs for discriminating bills of countries or regions which are to be discriminated and for performing reset processing at the time of start of the bill discriminating/counting machine 10, and an operating-time discrimination-object selecting means 179b for switching the bills (sheets) which are to be discriminated to selected ones at the time of operating of the bill discriminating/counting machine 10. The operating-time discrimination-object selecting means 179b has a configuration in which a user can switch the discriminating programs to selected ones in order to perform the discriminating processing for desired bills during the operation.

The activation time discrimination-object selecting means 179a operate according to operation of a particular key of the operation buttons 18, e.g., operation of a “Mode key 18a”, at the time of start of the bill discriminating/counting machine 10, and specifically, upon starting the bill discriminating/counting machine 10 without pressing the operation buttons 18, the first-country discriminating program stored in the program ROM 173, e.g., the discriminating programs for US Dollar bills are read out, and are automatically stored in the SRAM 172 through the computation CPU 171 according to instructions from the control CPU 170.

On the other hand, upon pressing a particular key of the operation buttons 18, e.g., the Mode key 18a, at the time of start, the second-country discriminating programs, e.g., the discriminating programs for discriminating Japanese Yen bills, stored in the program ROM 173, are read out according to instructions from the control CPU 170, and the second-country discriminating programs thus read out are stored in the SRAM 172 through the electric circuit of the computation CPU 171.

That is to say, the activation time discrimination-object selecting means 179a automatically selects the first-country discriminating programs or the second-country discriminating programs according to the fact whether or not the user has pressed a particular key, e.g., the MODE key 179a, at the time of starting, and the selected discriminating programs are stored in the SRAM 172. Further, the user can confirm whether the SRAM 172 stores the first-country discriminating programs or the second-country discriminating programs.

Furthermore, the operating-time discrimination-object selecting means 179b have a configuration in which when the user presses a “CHANGE key” (switching key) 18b (see FIG. 1) of the operation buttons 18 during the operation of the bill discriminating/counting machine 10, the discriminating programs used for the operation can be switched when idling. For example, when the user presses the CHANGE key 18b during the operation of the bill discriminating/counting machine 10 under the first-country discriminating programs, the control CPU 170 transmits reset signals to the DSP (computation CPU) 171 so as to initialize the DSP 171, to clear the first-country programs stored in the SRAM 172 and to store the second-country discriminating programs in the SRAM 172. In this case, the second-country discriminating programs are stored in the SRAM 172 in the same way as with the start-time discriminating-object means 179a. On the other hand, when the user presses the CHANGE key 18b during the operation of the bill discriminating/counting machine 10 under the second discriminating programs, the control CPU 170 transmits reset signals to the DSP (computation CPU) 171 so as to initialize the DSP 171, to clear the second-country discriminating programs stored in the SRAM 172 and to store the first-country discriminating programs in the SRAM 172. Furthermore, upon turning off the power switch 163, the discriminating programs stored in the SRAM 172 are cleared, i.e., the SRAM 172 is cleared.

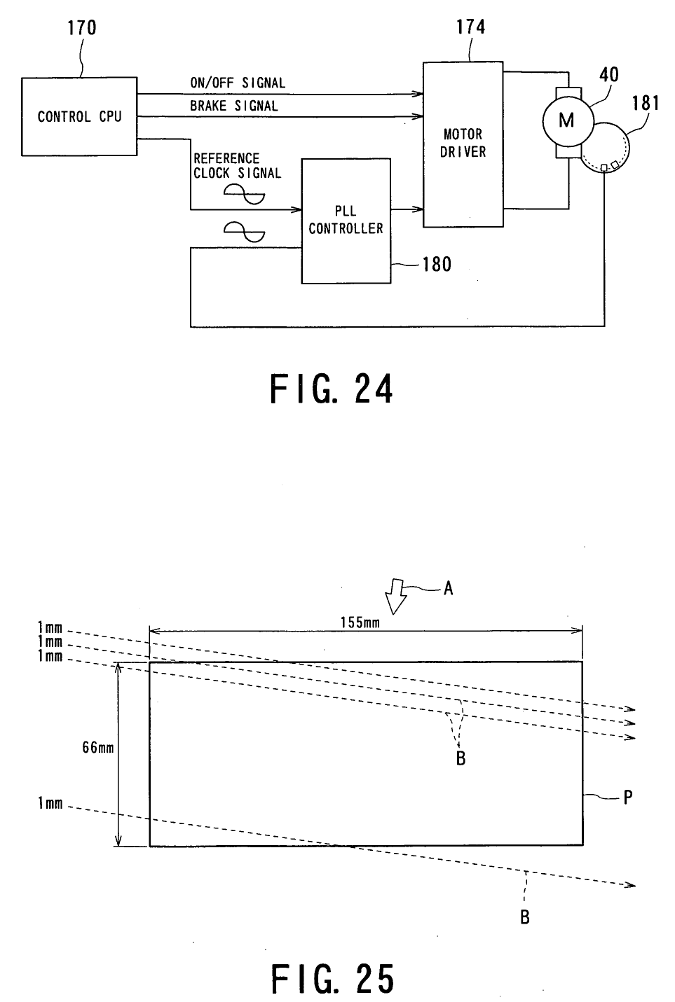

On the other hand, with the bill discriminating/counting machine 10, the control CPU 170 controls the transporting driving motor 40 as shown in FIG. 24. The control CPU 170 transmits ON/OFF signals and brake signals to the motor driver 174, and the motor driver 174 performs ON/OFF (driving/stop) control of the transporting driving motor 40 and brake control thereof.

On the other hand, the motor driver 174 receives control signals from a phase lock loop controller (PLL controller) 180 serving as an autonomous rotation control circuit so as to control rotation rate of the transporting driving motor 40. The PLL controller 180 receives reference clock signals from the control CPU 170 and encoder (rotation rate) signals from the encoder 44 for detecting rotation rate of the transporting driving motor 40, and performs comparison computation for these signals so as to output rotation-rate control signals for driving the motor driver 174.

That is to say, with the transporting driving motor 40, while ON/OFF (start/stop) of the motor driver 40 and control of the brake are performed according to the control signals (ON/OFF signals, brake signals) generated from the control CPU 170, control of rotation rate of the transporting driving motor 40 is performed according to signals output from the PLL controller 180. The PLL controller 180 serves as an autonomous rotation control circuit for the transporting driving motor 40, and the control CPU 170 does not control the PLL controller 180 so as to control rotation rate of the transporting driving motor 40, except for transmitting the reference pulse signals to the PLL controller 180.

The PLL controller 180 serves as means for reducing the processing load of the control CPU 170, wherein the control CPU 170 needs not to control the PLL controller 180, except for transmitting the reference pulse signals to the PLL controller 180 serving as an autonomous motor rotation control circuit, thereby reducing the processing load of the control CPU 170.

On the other hand, the control of the feeding driving motor 37 is performed in the same way as with the control of the transporting driving motor 40, and an autonomous rotation control circuit is provided in the same way as with the PLL controller 180.

With the present embodiment, while the control CPU 170 does not perform the control of rotation rate of the feeding driving motor 37 and the transporting driving motor 40, the PLL controller 180 performs the control thereof. With an arrangement in which the control CPU 170 controls the rotation rate of the motor, the control CPU 170 needs to monitor the rotation rate of the motor and control the motor at all times, leading to increased interrupt processing of the control CPU 170, resulting in a problem that the control CPU 170 may not be able to perform other processing for the control system in a predetermined period of time. With the present embodiment, the bill discriminating/counting machine 10 includes the PLL controller 180 serving as an autonomous motor rotation control circuit and has a configuration in which the PLL controller 180 performs control of the rotation rate of the motor, thereby reducing the processing load of the control CPU 170.

As shown in FIG. 22, the computation control system 166 includes the computation CPU 171 connected to the control CPU 170 in order to further reduce the processing load of the control CPU 170. The control CPU 171 is included for performing computation processing for detection signals (scan data) received from the sensors, and a calculation-dedicate DSP is employed as the computation CPU 171 so as to reduce the processing time for discriminating the denomination of each bill.

With an arrangement in which the discrimination is made for bills of a predetermined single country, a CPU having processing performance required for processing for the aforementioned bills should be employed as the computation CPU 171, but the bill discriminating/counting machine 10 has the advantage of discriminating the bills of multiple countries. With the present embodiment, the bill discriminating/counting machine 10 has the advantage of discriminating the bills of respective countries only by switching the discriminating program for the corresponding country without modification of the counting-machine main unit 11 for each country. Further, the discriminating programs for discriminating the bills of each country are stored in the primary-country-bill-discriminating program ROM 173 along with addressing numbers.

There are several denominations of the bills of countries wherein large computation amounts of the discriminating programs are required, and accordingly, it is necessary to provide a relatively high-performance control CPU in order to discriminate bills of each country with the single control CPU, leading to a problem of high costs.

With the bill discriminating/counting machine 10, the computation CPU 171 having high-speed calculation performance is included as well as the control CPU 170 so as to exhibit sufficient computation performance for performing the discriminating programs, thereby handling the bills of each country. While the computation CPU 171 is connected to the memory 172, a calculation-dedicated DSP is employed as the computation CPU 171 for processing the scan data within a predetermined period of time and for discriminating the denomination of each bill in a period of time as short as possible.

On the other hand, the bill discriminating/counting machine 10 needs to complete the discrimination of the denomination of each bill in a period of 50 m sec or less in order to exhibit the rate of 1200 sheets of the processed bills per minute, for example, and accordingly, the bill discriminating/counting machine 10 needs to exhibit the high-speed processing performance as well as precision for discriminating the denomination of each bill.

With the bill discriminating/counting machine 10, the line sensor 65 is employed as a sheet discriminating unit 63 for discriminating the denomination of each bill. As shown in FIG. 17 through FIG. 20, the line sensor 65 is a transmission light detector including a light-emission device array wherein thirty-eight light-emission devices 153 are arrayed in the shape of a line with a pitch of 5 mm, and a photo-receptor array wherein thirty-eight photo-receptors 157 are arrayed in the shape of a line with a pitch of 5 mm, for example and has a configuration in which serial line scanning is performed for each detector. The serial line scanning is repeated, and specifically, the line scanning is repeated with a scanning pitch of 1 mm in the transporting direction of each bill as shown in FIG. 25, for example, whereby the scanning of the entire surface of the bill P to be discriminated is completed. The reason why a transmitted light sensor is employed as the line sensor 65 is that the transmitted light sensor exhibits high-speed light response as compared with a reflection light detector which is used for detecting both sides of the bill P which is to be discriminated.

Specifically, the line sensor 65 comprises a 38-channel (38-ch) transmitted light detector, and the line scanning is performed for the transported bill P which is to be discriminated as shown by broken arrows B in FIG. 25. In a case of the line scanning along the longitudinal direction of the bill P with the scanning pitch of 1 mm in the direction (bill-feeding direction) of the shorter side of the bill P, the thirty-eight detectors forming the light sensor 65 transmit the thirty-eight detection signals for each line scanning as scan data signals.

In a case of US Dollar bills, each bill has the length of 66 mm in the transporting direction (in the direction of the shorter side thereof), and the number of signal samples serving as the scan data is equal to (38×the number of scanning operations corresponding to the bill-feeding pitch), i.e., the number of scan data samples is 2,508. Accordingly, it is necessary to provide the computation-dedicated CPU 171 such as a DSP for performing high-speed computation processing in order to process the scan data samples in a predetermined period of time for discriminating the denomination of each bill. With the present embodiment, the computation CPU 171 is included, thereby reducing computation processing period of time for each bill P which is to be discriminated as much as possible.

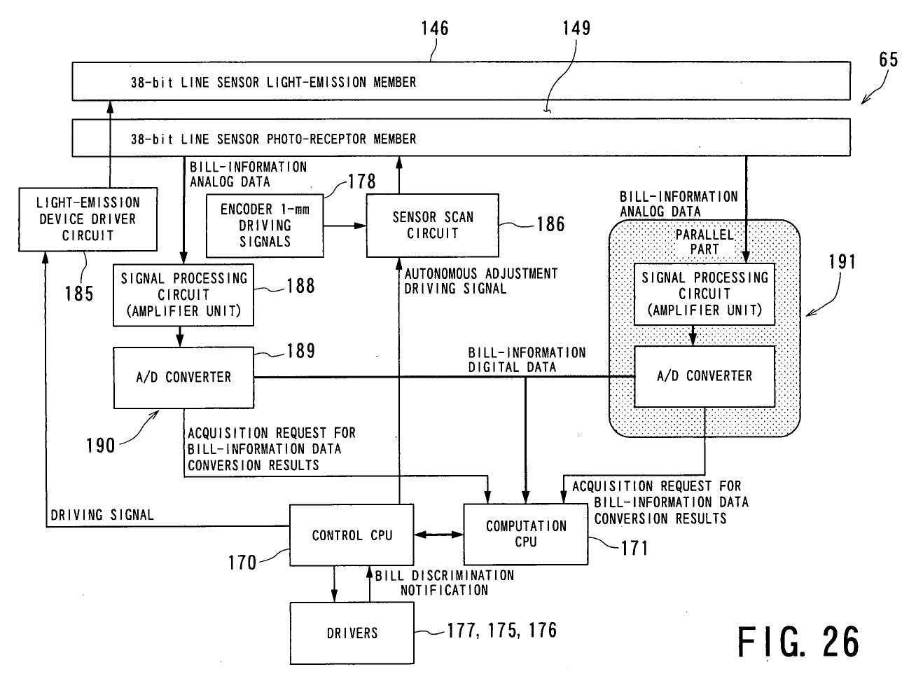

FIG. 26 is a functional block diagram which shows a scanning processing circuit for discriminating the kind of the bill P which is to be discriminated according to instructions from the computation CPU 171 using the line sensor 65.

The line sensor 65 is started according to control signals from the control CPU 170. With the light-emission unit of the line sensor 65, a light-emission device driver circuit 185 such as an LED driving circuit or the like is driven according to driving signals from the control CPU 170, and each light-emission device 153 (see FIG. 17 through FIG. 20) forming the light-emission sensor member 146 operates to thereby emit a light.

On the other hand, with the light-receiving unit of the line sensor 65, a sensor scan circuit 186 is driven according to driving signals from the control CPU 170. The sensor scan circuit 186 receives driving signals from an encoder 187, and outputs sensor scan start signals.

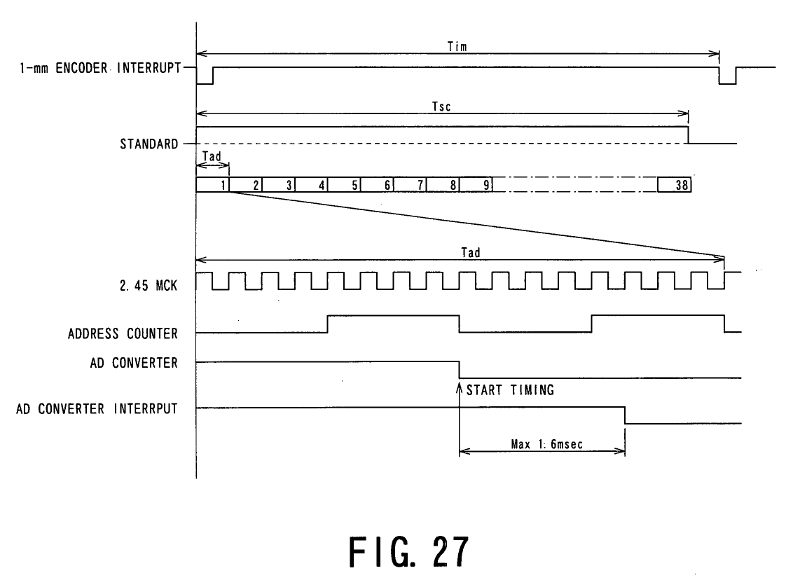

FIG. 27 shows the signals of a scan processing circuit 190 over time.

Upon the sensor scan circuit 186 shown in FIG. 26 receiving 1-mm driving signals from the encoder 187, for example, the internal counter of the sensor scan circuit 186 starts operations so that the sensor scan circuit 186 transmits scan start signals to the 38-bit line sensor 65 to thereby start the line scanning operations. A 1-mm encoder is employed as the encoder 178 (see FIG. 2), and in this case, the encoder 178 outputs driving signals for each feeding distance of 1 mm, and accordingly, the line scanning is performed with a cycle period of Tim corresponding to the feeding pitch of 1 mm during rotation of the feeding driving motor 53. That is to say, the “1-mm” of the 1-mm encoder 178 corresponds to the feeding pitch of 1 mm, and accordingly, the line scanning is performed for each bills with a scanning pitch of 1 mm.

In a case of a transporting rate of 1200 sheets per minute, the cycle period corresponding to the feeding pitch of 1 mm of the feeding driving motor 53 is calculated to be 318 μsec. In this case, the line scanning is performed for the 38-bit line sensor 65 in a period of Tsc (Tsc<Tim) when the scan start signals are generated.

In this case, scan address is allocated to each bit of the line sensor 65. The sensor scan circuit 186 uses 2.45 master clock signals (MCK) as reference clock signals corresponding to the processing speed, and accordingly, the processing period of time is a fixed value calculated from dividing of the 2.45 MCK. As a result, the access time Tad per bit is calculated to be 6.56 μsec, for example. The total scan time Tsc for 38 bits is calculated to be 249.28 μsec from the access time Tad. Further, the total scan time Tsc is constant, regardless of the transporting speed.

On the other hand, an AD converter 189 sends an interrupt to the computation CPU 171 for each bit. The interrupt is sent at a timing as follows. That is to say, A/D conversion of the AD converter 189 is started at a timing of 50% of the access time Tad for each bit. The AD converter 189 sends an interrupt within 1.6 μsec after start of the A/D conversion, and accordingly, A/D conversion is performed in a period between the start timing of the AD converter 189 and the interrupt switching time. The counter automatically stops after operations of the line sensor 65 for 38 bits, following which the operations thereof are performed for 38 bits according to an interrupt (driving signals) from 1-mm encoder 187, again.

The computation CPU 171 acquires scan data from the line sensor 65 only using driving signals from the 1-mm encoder 178, and upon completion of acquisition of the scan data for 38 bits, the line scanning for one feeding pitch is completed. After the completion of the line scanning of the line sensor 65 for one feed pitch, preparation is made for the next line scanning.

As described above, the line scanning is performed for each of the photo-receptors 157 for each line scanning. The line scanning is sequentially repeated, whereby the scanning is made for the entire surface of each bill. In this case, the encoder 178 is connected to the feeding roller (drum) 53 and generates 1-mm driving signals corresponding to the rotation of the feeding roller 53. For example, the feeding roller 53 is formed with a diameter of 50 mm, the encoder 178 fixed to the feeding roller 53 with the same axis as with the feeding roller 53 detects a feeding distance of 1 mm of the feeding roller 53, for example, and the sensor scan circuit 186 outputs driving signals for performing the line scanning for each of the photo-receptors 157 of the light-receiving sensor member 147 according to the 1-mm driving signals from the encoder 187. The driving signals generated from the encoder 178 is not restricted to the 1-mm driving signals. The encoder 178 may output the driving signals corresponding to the feeding pitch in the order of several mm. In this case, the scanning is performed for the entire surface of each bill with the feeding pitch of several mm.

With the present embodiment, the line scanning is performed for each of the photo-receptors 157 of the light-receiving sensor member 147, and the analog data signals including information about each bill thus detected from each of the photo-receptors 157 are transmitted to a signal processing circuit 188 so as to be subjected to data processing, as well as being amplified. The signal processing circuit 188 includes two system circuits of a density-system circuit and automatic-adjustment-system circuit, as well as an amplifier unit, and the system circuits is switched according to instructions from the computation CPU 171.

The analog data signals including bill information subjected to the signal processing in the signal processing circuit 188 are converted into digital signals by the AD converter 189, are transmitted to the computation CPU 171, and are subjected to the high-speed computation processing by the computation CPU 171. The processing data subjected to the computation processing by the computation CPU 171 serves as bill-discrimination (bill-denomination-discrimination) information, and is transmitted to the control CPU 170. The control CPU 170 outputs driving signals for driving the brake driver 175 or the gate driver 176 shown in FIG. 22, for example.

The signal processing period of time required for the scanning of the entire surface of each bill P, performed by the line scanning of 38-bit (38-ch) line sensor 65 with the single system scan processing circuit 189, is approximately 30 msec or less at the present technology level. Accordingly, the processing rate of bills is theoretically calculated to be approximately 2000 sheets of processed bills per minute based upon the aforementioned signal processing time.

While description has been made regarding an arrangement such that the serial line scanning is performed for the line sensor 65 by using the single-system scan processing circuit 190 with reference to FIG. 26, an arrangement may be made so that the light-receiving sensor member 147 of the line sensor 65 is divided into two, and a parallel scan processing circuit 191 is included so as to perform line scanning for the aforementioned two parts of the light-receiving sensor member 147 in parallel, thereby reducing scan period of time. Specifically, in this case, the processing rate is improved to approximately 4000 sheets of processed bills per minute.

With the line sensor 65 having a configuration in which a scan processing circuit for performing the scan processing is included for each channel so as to perform the scan processing for each channel in parallel, the scanning period of time is further reduced, but the scan processing circuits for 38 channels are required, leading to a problem of an excessive large size of the circuit board.

The bill discriminating/counting machine 10 according to the present embodiment has a configuration in which the single scan processing circuit 190 performs the processing for the line sensor 65 having thirty-eight detectors, thereby reducing the board size. On the other hand, with the bill discriminating/counting machine 10 having a configuration in which the parallel scan processing circuit 191 is included so that two scan system circuits of the scan processing circuit 190 and the scan processing circuit 191 perform serial scanning for two parts of the line sensor 65, each of which have 19 channels, respectively, the scanning time is reduced to the half of the scanning time described above. Specifically, the scanning can be theoretically performed for bills at a rate of approximately 4000 sheets of processed bills per minute.

On the other hand, as shown in FIG. 4 and FIG. 6, a bill is fed from the feeding roller (drum) 53 of the bill discriminating/counting machine 10 for each rotation. Accordingly, in order to feed the bills at a rate of 1200 sheets per minute, the feeding roller 53 needs to be rotationally driven at a rotational speed of 1200 rpm. In the same way, in order to feed the bills at a rate of 1500 sheets per minute, the feeding roller 53 needs to be rotationally driven at a rotational speed of 1500 rpm.

The feeding roller 53 is formed with a diameter of 50 mm, for example, and accordingly, in a case of transporting US Dollar bills with a width in the transporting direction of 66 mm, the bills are transported with a feeding pitch of approximately 157 mm, and accordingly, the bills are transported with an interval of approximately 90 mm between the adjacent bills. While the interval of 90 mm and the sufficient length of the transporting path 48 serve as a margin required for operating the switching gate 93 for switching the destination of the bill subjected to the bill-denomination discrimination in a sure manner, the interval is not restricted to 90 mm, and rather, an arrangement may be made so that the bills are transported with intervals therebetween equal to or greater than the width of each bill in the transporting direction.

In fact, in the event that feeding delay or slip occurs for a bill, this leads to a narrow interval between the adjacent transported bills, leading to a problem that the discrimination processing may not be able to be performed in a predetermined period of time. Accordingly, the bill discriminating/counting machine 10 includes a bill-detection sensor at a suitable position downstream from the feeding roller (drum) 53 for monitoring the interval between the adjacent transported bills, and further includes a transporting interval adjusting circuit such that, in a case of detecting a short transporting interval, the transporting interval adjusting circuit controls the feeding driving motor 39 so as to perform brake operations in order to immediately reduce the rotational speed of the motor, or controls the brake included in the roller shaft of the feeding roller (drum) 53 so as to immediately operate in order to delay the following bill, according to instructions from the control CPU 170, thereby adjusting the transporting interval so as to return to the normal state. The transporting interval adjusting circuit is included on the circuit board 165, and the control CPU 170 controls a part of functions thereof.

The bill discriminating/counting machine 10 includes the pocket 20 for storing the bills which have been rejected by the discriminating processing and has a configuration such that the transporting path 48 forks at a position downstream from the sheet discriminating unit 63 into two paths of a path toward the stacker 21 and a path toward the pocket 20. In this case, the switching gate 93 is disposed at a predetermined position on the transporting path 48, and an unshown gate solenoid performs switching of the switching gate 93.

However, the switching operations of the switching gate 93 is performed after the completion of bill-denomination discrimination, i.e., following the bill passing through the sheet discriminating unit 63. In order to obtain a margin of a period of time for completing the bill-discrimination, the distance between the sheet discriminating unit 63 and the switching gate 93 is preferably formed long.

On the other hand, bills are transported on the transporting path 48 at a high speed, and accordingly, the transporting path 48 is preferably formed as straight as possible in order to suppress jamming of bills. The layout wherein the transporting path 48 is formed straight leads to the increased size of the bill discriminating/counting machine 10, leading to a problem of poor utility on the desk. The bill discriminating/counting machine 10 of the present embodiment has a compact configuration in which, while the transporting path 48 is stored within the counting-machine main unit 11 in the shape of a zigzag, the path between the sheet discriminating unit 63 and the switching gate 93 is formed straight. The bill discriminating/counting machine 10 having such a configuration exhibits the discriminating processing performance at a processing rate of 1200 sheets per minute or more, as well as being formed small and compact so as to serve as a desk-top bill discriminating/counting machine. Specifically, the desk-top bill discriminating/counting machine 10 is formed with a width of the front surface of 330 mm, with a depth of 335 mm, and with a height of 300 mm, for example.

On the other hand, the bill discriminating/counting machine 10 includes the circuit board 165 serving as a control board shown in FIG. 22, and the computation processing system 166 includes a bus emulator circuit 195 for performing rapid graphic processing for displaying information on the display panel 17 (see FIG. 1). A general-purpose LCD graphic display (which is not a character display) may be employed as the display panel 17. Further, the LCD bus emulator circuit 195 is included as an interface circuit in order to adjust and suppress the difference in timing or speed of signal transmission/reception between the signal processing on the display panel 17 and the signal processing on the CPU 170. The LCD bus emulator circuit 195 is formed of a PLD in the form of a single chip.

The display panel 17 formed of a full-graphic display LCD or the like is driven according to instructions from the control CPU 170, and a great amount of data is transmitted and received therebetween. With a configuration in which the control CPU 170 directly controls the display panel 17 formed of a general-purpose display panel, the single control CPU 170 performs all the great number of processing steps, leading to a problem of an excessively heavy load on the control CPU 170.

With the present embodiment, the control CPU 170 performs all the control processing for driving the drivers 174, 175, 176, and the like, and accordingly, the load thereof is preferably reduced as much as possible. On the other hand, an I/O port of the control CPU 170, of which there are not many, can be used for the controlling other than the drivers 174, 175, 176, and the like. However, the I/O port has various restrictions for use, i.e., the I/O port may not be able to used for controlling the operation panel 17. While an arrangement may be made such that a dedicated CPU is further included for directly controlling the display panel 17, the present bill discriminating/counting machine 10 has a configuration so that the bus emulator 195 serving as an interface circuit is further included between the single control CPU 170 and the display panel 17 formed of a general-purpose display panel. There is no difference in display on the display panel 17 formed of a general-purpose display panel between the configuration in which the bus emulator circuit 195 controls the display panel 17 and the configuration in which the control CPU 170 directly controls the display panel 17.

With such a configuration in which the bus emulator circuit 195 is further included, the control CPU 170 can transmit 8-bit information by a single command at the same time for controlling the display panel 17, for example, thereby improving processing speed. The configuration, in which the bus emulator 195 is further included, effects marked reduction of the load of the control CPU 170 for controlling the display panel 17, thereby improving processing speed.

Furthermore, an arrangement may be made wherein an I/O port is included on the control CPU 170, and the I/O port is connected to the display panel 17 so that the control CPU 170 is connected to the display panel 17, instead of a configuration including the bus emulator circuit 195. Furthermore, in a case that there is no difference in transmission/reception timing or speed of signal processing between the control CPU 170 and the display panel 17, the control CPU 170 may be directly connected to the display panel 17.

On the other hand, the sensor processing system 168 on the circuit board 165 shown in FIG. 22 can be divided into a line sensor processing system circuit 196 and a magnetic sensor processing system 197 or a UV sensor processing system. The line sensor processing system 196 is connected to the line sensor 65 through a line sensor connector 198. Further, reference numeral 189 denotes an A/D converter for converting operation data analog signals received from the line sensor 65 into digital signals.

The magnet sensor (MG sensor) processing system 197 is connected to an MG sensor serving as the genuine/forged discriminating sensor 66 through an MG connector 200. Reference numeral 201 denotes a connector for connecting a UV sensor, which is used at the time of using a UV sensor as the genuine/forged sensor 66. Reference numeral 202 denotes a condenser, 203 denotes a test point for adjustment and test, and reference numeral 204 denotes an adjusting volume for the MG sensor.

Furthermore, the power supply system 167 includes a regulator 210 with great heat generation, and a heat sink 211 for releasing the heat generated from the regulator 210. Reference numeral 212 denotes a resistance array.

The discriminating processing for bills by means of the bill discriminating/counting machine 10 will be described hereunder.

[1] Method For Setting Discriminating Programs At The Time of Turning On The Power Supply

Upon turning on the power supply switch 163 shown in FIG. 23 so as to start the bill discriminating/counting machine 10, the control CPU 170, the computation CPU 171, and the SRAM 172 are reset according to reset signals from the power supply system 167, and the discrimination-object selecting means 179 automatically operate so that the first-country programs are automatically stored in the SRAM 172.

Specifically, the control CPU 170 reads out the first-country discriminating programs stored in the program ROM 173 as well as the control system programs and transmits the first-country discriminating programs to the SRAM 172 through the DSP (computation CPU) 171, and the SRAM 172 stores the first-country discriminating programs, thus completing the preparation for the discriminating processing of the bill discriminating/counting machine 10.

Upon turning on the power supply without pressing any operation buttons 18, the bill discriminating/counting machine 10 is automatically started so as to store the first-country discriminating programs in the SRAM 172 through the automatic control processing of the discrimination-object selecting means 179.

[2] Method For Switching The Discriminating Programs At The Time Of Turning On The Power Supply

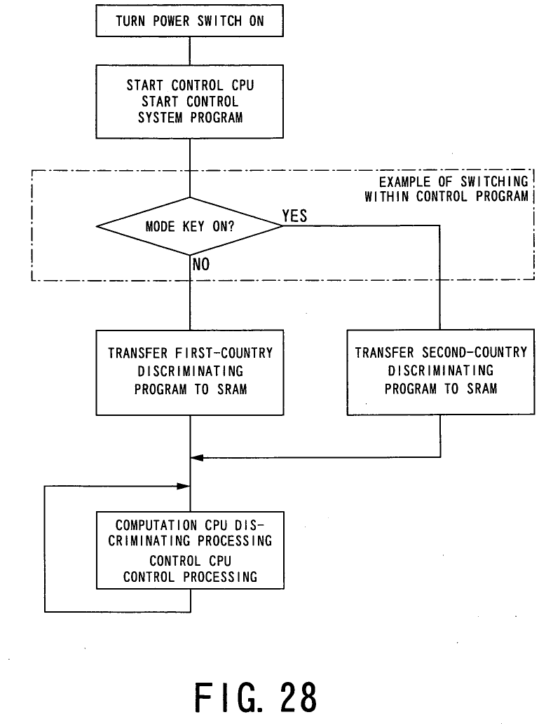

In order to start the bill discriminating/counting machine 10 with the second-country discriminating programs stored in the SRAM 172 at the time of turning on the power supply, the user turns on the power switch 163 (see FIG. 23) while pressing a particular key of the operation buttons 18, e.g., the MODE key 18a. FIG. 28 is a flowchart which shows switching process for switching the discriminating programs at the time of the operation start.

Upon turning on the power supply switch 163 so as to start the power supply, the power supply circuit of the power supply system 167 outputs reset signals so as to reset the control CPU 170, the computation CPU 171 and the SRAM 172, and the control CPU 170 is then started so as to immediately read out the control system programs from the program ROM 173.

Upon starting the power supply while pressing a particular key, e.g., the MODE key 18a, the control CPU 170 accesses the second-country discriminating programs, reads out the second-country discriminating programs and stores these programs in the SRAM 172 through the computation CPU 171, according to determination programs included in the control system programs for determining the operation state of particular keys. In this case, the control CPU 170 makes preparation for the discriminating processing of the computation CPU 171 and the control processing of the control CPU 170, wherein the control CPU 170 controls the computation CPU 171 to perform computation processing using the second-country discriminating programs stored in the SRAM 172.

That is to say, upon starting the power supply without pressing a particular key, e.g., the MODE key 18a, the first-country discriminating programs are stored in the SRAM 172, and on the other hand, upon starting the power supply while pressing the MODE key 18a, the second-country discriminating programs are stored in the SRAM 172.

[3] Method For Discriminating Bills To Be Discriminated

As described above, the bill discriminating/counting machine 10 is started, the SRAM 172 stores the first-country discriminating programs, for example, by actions of the discrimination-object selecting means 179, and preparation is completed for discrimination processing of the computation CPU 171 and the control CPU 170. Subsequently, the discriminating processing is performed for bills which are to be discriminated according to the first-country discriminating programs.

Upon the user performing predetermined operations of the operation buttons 18 on the operation panel 16, the bill discriminating/counting machine 10 performs the discriminating processing for bills. In the same way, when the user performs the predetermined operations of the operation buttons 18, the discrimination state for bills, which are to be discriminated, is displayed on the display panel 17 such as LCD or the like.

The operation buttons 18 serve as key switches, e.g., eleven types of key switches. The user can select a suitable processing mode for bills which are to be discriminated by operating the operation buttons 18 on the operation panel 18. The processing modes, which can be selected by the user through the operation buttons 18, are shown in the following table, in which US Dollar bills are handled and discriminated.

It is further to be noted that each operation button 18 is connected to the corresponding key switch, and the user can operate a desired key switch by operating the corresponding operation button 18.

TABLE 1

| Operating | |
|---|---|
| Button | Arrangement And Use Of Operating Button |
| 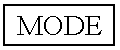 | While selecting the bill to be discriminated, switching of the four counting modes of FREE (count of number of sheets), MIXED (discriminating/counting mixed denominations), SINGLE (different denomination detection count), SORT (denomination detection count) and switching of SET-UP (selecting and setting functions to be attached to the four count modes) MODE is performed by pressing operations of this operating |
| # button. Also, the selected count mode is displayed on the display panel (LCD). | |
| 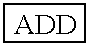 | The number of sheets (or monetary amount) counted this time is added to the number of sheets (or monetary amount) counted the previous time, and displayed on the display panel (LCD). |
| 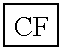 | In the event that MG MODE or UV MODE is set in the SET-UP mode, pressing this operating button adds counterfeit detection functions. In the event that counterfeit detecting functions are added, the letters MG or UV are displayed on the display panel (LCD). |
| 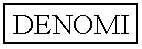 | Displays the details of denominations discriminated/counted in the MIXED, SINGLE, and SORT modes. In the event that there are instructions for displaying the grand total with the “GT” key, the details of GT (grand total display) are displayed below. |
| 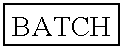 | Each time an operating button for specifying the number of sheets for batch processing is pressed, this changes between “100 sheets”, “50 sheets”, “25 sheets”, “10 sheets”, “5 sheets”, and “no specification”. Also, in the SET-UP mode, the specification for these numbers can be changed. In the event of changing the specification of the number of sheets one at a time, the “ρ” and “σ” keys can be |
| # pressed to change the number of sheets for batch processing. | |
| 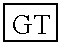 | Displays the grand total of the number of sheets (or monetary amount) counted so far. Pressing again displays the number of sheets (or monetary amount) counted the last time on the display panel (LCD). |
| 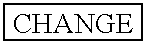 | This operating button is operated in the event of switching the bill which is the object of discrimination while in operating standby. |
| 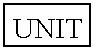 | The display switches between displaying monetary amount display and count of sheets display each time this operating button is pressed. In the event that monetary amount display is selected, a $ symboy (¥ symbol) is displayed in front of the figure. |
| 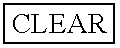 | This operating button is used for canceling a transporting error or clearing a count value for each count from the grand total. This is also used for canceling an item selected in the SET-UP mode. |
| 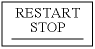 | Pressed to start or restart counting. Also used for setting a selected item in the SET-UP mode. |
| 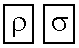 | Used for incrementing or decrementing the number of batch sheets one at a time, selecting items in the SET-UP mode, and selecting specified denominations in the SINGLE mode or denominations for the DENOMI display. |

Upon selecting the discrimination conditions for the bills which are to be discriminated with the operating button 18, supplying the bills P to the hopper 15 and operating the bill discriminating/counting machine 10, the feeding driving motor 39 and the transporting driving motor 40 are started so as to drive the sheet feeding driving system 35 and the sheet transporting driving system 37 making up the sheet transporting device as shown in FIG. 2 and FIG. 3.

Upon driving the sheet feeding driving system 35, the sending roller 50 and the feeding roller (drum) 53 are driven synchronously with each other, as shown in FIG. 4. The sending roller 50 sends the sheets such as bills stacked on the hopper 15 to the transporting path 48 one by one from the bottom end of bills. On the other hand, the feeding roller (drum) 53 feeds each bill 14 sent from the sending roller 50 to the straight transporting path 48a of the transporting path 48.

A bill 14 is fed for each rotation of the feeding roller 53. The sending roller 50 and the feeding roller 53 have a configuration in which the balancer weights 52 and 56 are included as shown in FIG. 5 and FIG. 6 for keeping rotation balance, thereby enabling the rotation thereof at a rotation rate of 1200 rpm or more.

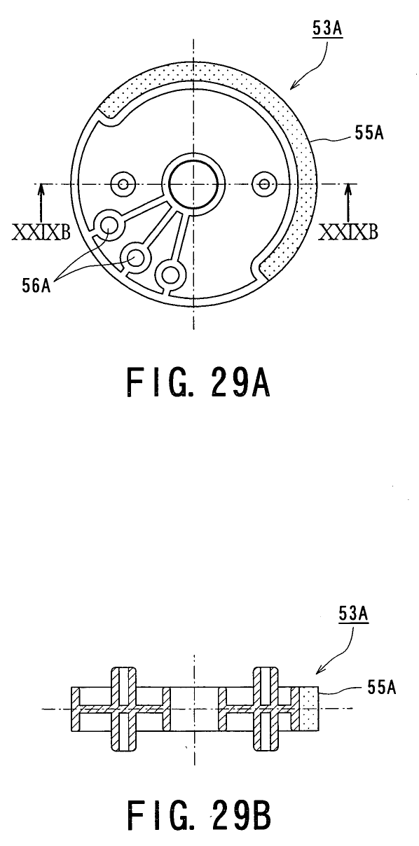

The feeding roller may have a configuration shown in FIG. 29A and FIG. 29B. A feeding roller 53A has a configuration in which a friction member 55A formed in the shape of an arc is included at a part of circumference thereof, and a balancer weight 56A is integrally mounted at a position facing the friction member 55A in the diameter direction.

The straight transporting path 48a is formed straight and downward on the rear side within the counting-machine main unit 11 from the feeding roller 53 included on the upper portion thereof to the reversal sending driving roller 70 set below, and the bills 14 transported to the straight transporting path 48a, are subjected to the discrimination of the denomination of bills, discrimination whether each bill is whole or damaged, and discrimination whether each bill is genuine or forged, by the sheet discriminating unit 63.

The sheet discriminating unit 63 includes at least the line sensor 65 and the genuine/forged discriminating sensor 66. Furthermore, the sheet discriminating unit 63 may further include the front/back discriminating sensor 64 for discriminating the front and back of each bill.

The line sensor 65 comprises a 38-bit transmitted-light detector having a configuration such that thirty-eight detectors are arrayed in the shape of a line with a predetermined pitch of 5 mm across the straight transporting path 48a, for example. With the present embodiment, the line scanning is performed for the line sensor 65, whereby the bill 14 (P) which is to be discriminated is scanned along the longitudinal direction thereof as shown by broken arrows B in FIG. 25.

While each bill P is transported at a high speed along the transporting path 48 with the shorter side thereof parallel to the transporting direction, in actual, the bills P transported on the transporting path 48 with some slant are permissible. The permissible angle between the longitudinal direction of the bill P which is to be discriminated and the width direction of the transporting path 48 is around 12° to 15°.

Line scanning is performed for the line sensor 65 along the longitudinal direction of the bill P which is to be discriminated, and the line scanning is consecutively repeated while feeding the bill with a pitch of 1 mm. Due to the scanning of the line sensor 65, the entire surface of each bill P, being transported over the straight transporting path 48a, is scanned.

The computation CPU 171 makes a comparison between the 38-ch scan data obtained from the line sensor 65 and the discriminating programs stored in the SRAM 172 with suitable threshold values by using the fact that there is difference in a pattern or brightness of the bill P between the printed portion and the non-printed portion thereof, thereby enabling discrimination of the denomination of the bill P to thereby enable the discrimination whether the bill P is whole or damaged. For example, in the event that the bill has exhibited small difference in brightness thereof, the bill is determined to be damaged, and on the other hand, in the event that the bill has exhibited great difference in brightness thereof, the bill is determined to be whole. Note that in a case of using the detector for scanning a part of the bill P which is to be discriminated, not the entire surface thereof, discrimination whether the bill is genuine or forged is impossible.

With the present embodiment, the line sensor 65 detects and scans the entire surface of the bill P which is to be discriminated, thereby enabling detection of bills with folded corners, damaged bills, and folded bills to thereby enable the discrimination of these detected bills as bills rejected from the bills which are to be discriminated.

Furthermore, the genuine/forged discriminating unit 66 forming the sheet discriminating unit 63 performs discrimination whether each bill is genuine or forged. While the genuine/forged discriminating unit 66 is formed of a magnet sensor (MG sensor), for example, the genuine/forged discriminating unit 66 may be formed of a combination of the magnet sensor and a UV sensor. Furthermore, an arrangement may be made so that the MG sensor and the UV sensor of the genuine/forged discriminating unit 66 are disposed along the longitudinal direction of the transporting path 48a.

The bill P, which is to be subjected to the front/back discrimination, the discrimination of the denomination thereof, the detection of folded-bill error and the discrimination whether the bill is genuine or forged, by the sheet discriminating unit 63 arrayed along the straight transporting path 48a, is guided to the U-shaped curved transporting path 48b formed on the lower portion on the rear side of the counting-machine main unit 11. The curved transporting path 48b is formed of a gently curved path with a sufficient length serving as a margin of period of time for discriminating processing performed by the sheet discriminating unit 63, as well as with a gentle radius of curvature of 50 mm or more in order to prevent the jamming phenomenon of bills, by providing a sufficient length for the curved transporting path 48b.

With the present embodiment, the gate timing sensor 75 formed of a transmitted light sensor is disposed at the entrance of the crest-shaped transporting path 48c formed downstream on the transporting path from the U-shaped curved transporting path 48b for detecting whether or not the bill P subjected to the discriminating processing by the sheet discriminating unit 63, has passed therethrough. The control CPU 170 shown in FIG. 22 and FIG. 23 drives the gate solenoid 176 according to the detection signals received from the gate timing sensor 75, and the solenoid 176 thus driven performs the switching operation of the switching gate 93 with a suitable timing.

In the event that the sheet discriminating unit 63 has determined that the bill which is the object of the discrimination is whole and genuine without folding or damage, the switching gate 93 is switched so as to guide the bill to the stacker 21. On the other hand, in the event that the sheet discriminating unit 63 has determined that the bill is folded, damaged, or forged, the switching gate 93 is switched with a suitable timing given by the gate timing sensor 75 so as to guide the bill to the reject transporting path 48d toward the pocket 20.

Upon switching the switching gate 93 to the eject transporting path 48d, the bill is guided from the crest-shaped transporting path 48c to the eject transporting path 48d, following which the bill is guided from the eject transporting path 48d to the pocket 20. Upon opening the support member 23, the user can easily take out the bills guided to the pocket 20 from the front side. On the other hand, the stacker 21 is formed with a widely opened upper side, and accordingly, the user can easily take out the bills guided to the stacker 21 through the opening.

On the other hand, the discrimination processing results obtained by the bill discriminating/counting machine 10 are displayed on the display unit of the display panel 17 formed of a full-graphic LCD or the like at a suitable timing, and the user can immediately confirm the discrimination processing results through the display panel 17. An arrangement may be made so that the discrimination processing results are printed on a paper sheet by a built-in copier, not shown.

The bill discriminating/counting machine 10 has a performance such that the bills P stacked on the hopper 15 are subjected to the discrimination processing at high processing rate of 1200 sheets per minute or more and has a configuration in which the transporting path 48 is formed with a sufficient length in order to perform high-speed and stable discrimination processing for each of the bills P, even in a case of the small-sized and compact desk-top bill discriminating/counting machine 10.

In order to form the transporting path 48 with a sufficient length, the transporting path 48 is formed in the zigzag shape within the counting-machine main unit 11 of the bill discriminating/ counting machine 10. With such a configuration according to the present embodiment, the transporting path 48 is formed in the shape of a zigzag, and each curved portion thereof is formed with a sufficient radius of curvature, i.e., the transporting path 48 is formed with a great radius of curvature, thereby preventing the jamming phenomenon of bills on the transporting path 48.

In a case that the bill discriminating/counting machine 10 performs the discrimination processing at a processing rate of 1200 sheets per minute, for example, each bill is transported on the transporting path 48 at a markedly high feeding speed of 3.14 m/sec, for example, and accordingly, this may lead to the jamming phenomenon of bills on the transporting path 48.

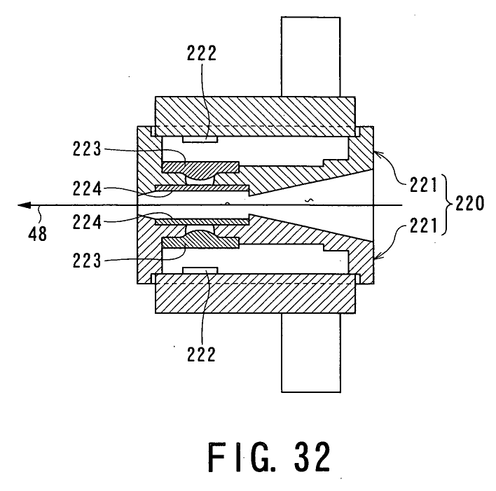

Upon jamming the bills, the jamming of the bills is detected by various types of sensors disposed along the transporting path 48, and the brake driver 175 is immediately driven through the control CPU 170 shown in FIG. 22 so as to immediately perform the braking operations of the brake device such as an electromagnetic brake or the like to thereby immediately stop the rotation of the feeding driving motor 39 shown in FIG. 32. Upon the emergency stop of the driving motor 39, the sheet feeding driving system 35 is stopped to be driven, and the feeding roller (drum) 53 (see FIG. 4) is also stopped to rotate. That is to say, upon stopping the feeding roller 53, the feeding of the bills is stopped.

On the other hand, in the event that the jamming phenomenon occurs partway along the transporting path 48, the transporting driving motor 40 (see FIG. 3) is also stopped to drive. The stopping of this motor driving is effected somewhat later than the emergency stop of the feeding driving motor 39. Upon the driving of the sheet transporting driving system 37 being stopped, sheets partway along the transporting path 48 cannot be guided to the stacker 21 or the pocket 20, and accordingly exist partway along the transporting path 48. However, in this case, the various transporting path opening mechanisms 112, 125, and 130 are provided so that the transporting paths 48a, 48b, 48c, and 48d can be opened wide, so that the jammed bills or remaining bills can be easily extracted and removed from the transporting path 48.

For example, in the event that a jammed bill is stopped at the straight transporting path 48a or the U-shaped curved transporting path 48b, the rear cover 120 is opened as shown in FIG. 7 through FIG. 9, and the rear-side transporting path opening mechanism 112 is opened, so that the rear opening guide arm mechanism 114 turns around the support shaft 113, while on the other hand the upper guide arm 115 turns around the support shaft of the lower guide arm 116, and the straight transporting path 48a and the U-shaped curved transporting path 48b formed at the rear of the counting machine main unit 11 is opened wide to the rear side. Opening the straight transporting path 48a and the U-shaped curved transporting path 48b allows the jammed bills or remaining bills at these portions to be easily extracted and removed from the transporting paths 48a and 48b.

After removing the jammed bill from the transporting paths 48a and 48b, the handle lever 117 is gripped, and the wrist pin of the rear opening guide arm mechanism 114 is pressed into the lock means 118 and engaged, as shown in FIG. 8, so as to be retained, whereby the transporting paths 48a and 48b can be closed, and the rear-side transporting path opening mechanism 112 can be held in the set state. By setting the rear-side transporting path opening mechanism 112 in the set state, the straight transporting path 48a from the feeding roller 53 to the reversal driving roller 70 and the U-shaped curved transporting path 48b formed at the portion of the reversal driving roller 70 are formed, respectively, at the rear side of the counting machine main unit 11.

Furthermore, in the event that the bill jamming phenomenon occurs at the crest-shaped transporting path 48c of the bill discriminating/counting machine 10, the crest-shaped transporting path opening mechanism 125 is opened from the front side of the counting machine main unit 11, as shown in FIG. 10. The crest-shaped transporting path opening mechanism 125 is pressed downwards against the spring force of the paired spring 129 with the handle lever 128, which turns the opening guide arm mechanism 126 on the support shaft 113, so that the crest-shaped transporting path 48c is opened wide toward the front of the counting machine main unit 11.

Accordingly, the bills stopped in the crest-shaped transporting path 48c can be easily extracted toward the front of the counting machine main unit 11 through the stacker impellers 90 forming a pair.

Further, in the event that the bill jamming phenomenon occurs at the reject transporting path 48d of the bill discriminating/counting machine 10, the reject transporting path opening mechanism 130 is operated as shown in FIG. 11. The reject transporting path opening mechanism 130 are opened by pressing the operation button 138 shown in FIG. 1 so that the engaging hook 136 is operated via the cam mechanism 140 as shown in FIG. 12 and FIG. 13, thereby releasing the bridge pin 135 of the reject transporting path opening mechanism 130 from the engaging hook 136.

Upon the bridge pin 135 being released from the reject transporting path opening mechanism 130, the reject opening guide arm mechanism 132 is turned far on the support shaft 131 under its own weight. At this time, the support member 23 is preferably set so as to be free from the pocket receiver 22.

Upon the reject opening guide arm mechanism 132 being turned far on the support shaft, the pocket receiver 22 is also integrally turned in the counter-clockwise direction as shown in FIG. 11, so the counting machine main unit 11 is opened wide at the front surface portion. By opening of the front surface of the counting machine man unit 11, the reject transporting path 48d is opened wide toward the front of the counting machine man unit 11, so the bills remaining on the reject transporting path 48d can be removed.

Furthermore, although an example of performing discrimination processing of 1200 bills as sheets in one minute has been described with one embodiment of the sheet discriminating/counting machine, the discrimination processing of bills may performed at the high speed of 1500 sheets per minute, or even faster high-speed discrimination processing may be performed. In the event of performing high-speed processing of bills of 1500 sheets per minute, it is necessary to rotationally drive the feeding roller (drum) at 1500 rpm, and the discrimination processing time of the discrimination unit is to be synchronized with the rotational driving of the feeding roller. Further, the bills may be processed as well at low speed of about 700 sheets per minute to 800 sheets per minute.

[4] Method For Switching Discriminating Program With CHANGE Key Of Sheet Discriminating/Counting Machine

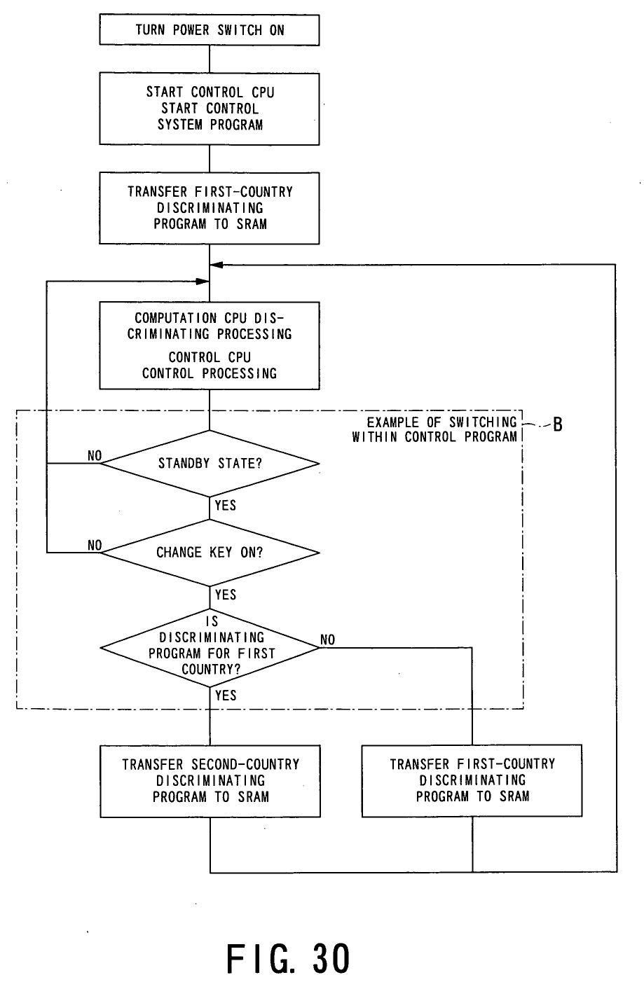

The sheet discriminating/counting machine 10 can switch the discriminating programs recorded in the SRAM 172 and stored through the pressing (ON) operations of the CHANGE key 18b (see FIG. 1) during the operation. The flowchart for this switching is shown in FIG. 30.

FIG. 30 is a flowchart of a case for changing the discriminating program with the sheet discriminating/counting machine 10 in the event that the discrimination processing of the computation CPU 171 and the control processing of the control CPU 170 are being performed based on a first-country discriminating program stored in the SRAM 172, and the switching processing by a control system program read into the control CPU 170 is carried out within the dotted region B.

At this time, the control processing at the control CPU 170, with the sheet discriminating/counting machine 10 operating, discriminates whether or not the state is an operating standby state is determined, and upon the CHANGE key 18b being operated by being pressed (ON) in the operating standby state, it is determined whether or not the discriminating program operating is the first-country. In the event that operating is carried out based on the first-country-discriminating program, the control CPU 170 reads out the second-country discriminating program from the program ROM 173, transfers this to the computation CPU 171 and is stored in the SRAM 172. By storing the second-country discriminating program in the SRAM 172, the first-country discriminating program stored in the SRAM 172 is reset before and is switched to the second-country discriminating program.

The computing processing of the computational CPU 171 and control processing of the control CPU 170 are carried out based on the second-country discriminating program recorded in the SRAM 172 and stored.

Thus, the pressing (ON) operations of the CHANGE key 18b of the sheet discriminating/counting machine 10 switches the discriminating program stored in the SRAM 172 from the first-country discriminating program to the second-country discriminating program, and subsequently, the control processing of the control CPU 170 based on the control program and, thereafter, the discrimination processing of the computational CPU 171 based on the second-country discriminating program, are performed.

In the event of switching the discriminating program to the first country while the sheet discriminating/counting machine 10 is performing discrimination processing of the bills to be discriminated, based on the second-country discriminating program, the CHANGE key (ON) is pressed to thereby switch the discriminating program from that for the second country to the first country, and subsequently, the control processing of the control CPU 170 based on the control program and the discrimination processing of the computation CPU 171 based on the first-country program, are carried out.

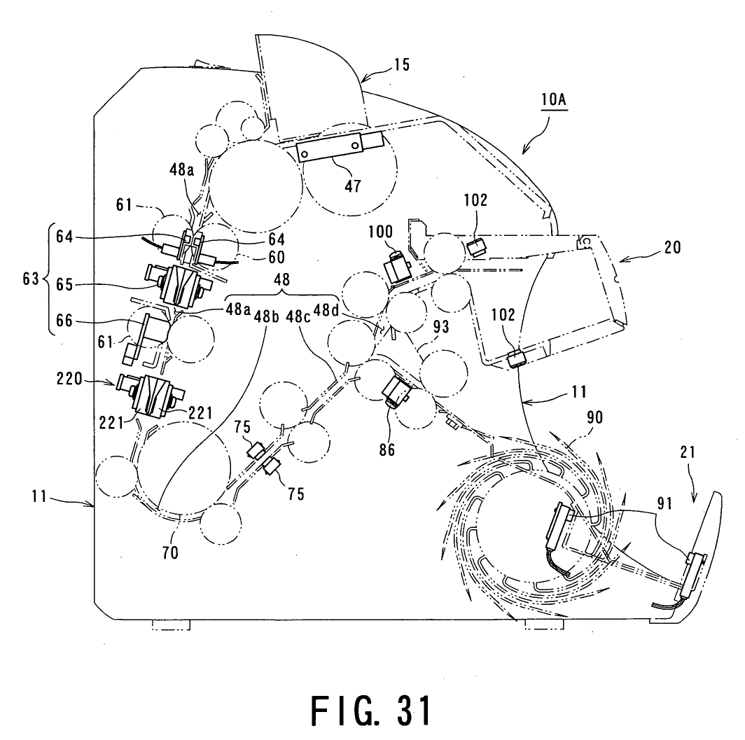

FIG. 31 and FIG. 32 illustrate another embodiment of the sheet discriminating/counting machine according to the present invention.

This sheet discriminating/counting machine is also a desk-top bill counting machine for discriminating and counting bills, for example, as sheets, at a high speed of 1200 or more per minute.

The bill counting machine 10A has a sterilization processing device 220 for sterilizing or disinfecting bills transported in addition to the bill counting machine 10 illustrated in FIG. 1 through FIG. 30, and other configurations are essentially unchanged, so that these will be denoted with the same reference numerals and description thereof will be omitted.

The sterilization processing device 220 is provided partway along the transporting path 48 for the bills to be discriminated. FIG. 31 illustrates an example of the sterilization processing device 220 disposed downstream of the direct transporting path 48a or between the direct transporting path 48a and the U-shaped curved transporting path 48b. This may also be provided at another position on the transporting path 48, such as at the entrance side of the direct transporting path 48, for example. The basic configuration of the sterilization processing device 220 may be the same as the structure of the line sensor 65 shown in FIG. 17 through FIG. 20, for example.

The sterilization processing device 220 has ultraviolet ray irradiating devices 221 and 221 integrally configured on both sides of the transporting path 48 as shown in FIG. 32, and the ultraviolet ray irradiating devices 221 and 22 1 have ultraviolet ray emitters 222 extending on the width direction of the transporting path 48. The ultraviolet ray emitters 222 may be formed in a long and slender line-shaped form extending in the width direction of the transporting path 48, or may be formed with a great number of ultraviolet light emitting LEDs arrayed in a line form.

The sterilizing ultraviolet rays emitted from the ultraviolet ray emitters 222 are irradiated in a line form in the width direction of the transporting path 48 from both sides, via lens members 223 and transparent plates 224. The irradiation of the sterilizing ultraviolet rays in line form from both sides leads to the irradiation of the sterilizing ultraviolet rays on the entire surface of the bills guided over the transporting path 48 from both sides, thereby enabling sterilization or disinfecting of germs on the surface of the bills.

While FIG. 31 and FIG. 32 illustrate an example of using an ultraviolet ray sterilizing processing device as the sterilization processing device 220, the sterilization processing device may be a chemical sterilization processing device having an ozone generator, or a thermal sterilization processing device using sterilization by heat. In the event of using an ozone generator, consideration must be given so that the amount of generated ozone, which is active oxygen, is controlled, and that the ozone is contained internally so as to be prevented from flowing out.

Although there has been described as an example of one embodiment of the preset invention an example of the sheet discriminating/counting machine performing discriminating/counting of bills of two countries to be discriminated, various modifications may be made to the discriminating programs and switching software shown in FIG. 28 and FIG. 30 regarding the bills to be discriminated, thus enabling the discrimination from the discriminating programs for three or more countries, and furthermore, the discriminating/counting can be performed for various types of sheets besides bills, such as bond certificates like national bonds and corporate bonds, tickets and coupons for railways, airlines, busses, etc., gift certificates, book coupons, stationery coupons, and like vouchers. In such case, it is necessary to program the discrimination patterns of the sheets to be measured in the program ROM 173 of the computation control system of the circuit board, for example.

Further, with the sheet discriminating/counting machine illustrated in one embodiment of the present invention, an example has been illustrated wherein the power source is placed at the bottom of the rear side of the counting machine main unit, and the reversal driving roller is disposed above the power source. The reversal driving roller can, however, be disposed near the bottom of the rear side of the counting machine main unit, by shifting the power source to dead space within the counting machine main unit. In this case, the length of the transporting path can be lengthened even further, which increase the speed. Furthermore, the diameter of the reversal driving roller can be further increased, thus increasing the radius of curvature of the U-shaped curved transporting path.

Moreover, with the sheet discriminating/counting machine illustrated in one embodiment, an example has been illustrated wherein the stacker is disposed at the lower front portion of the counting machine main unit and the pocket provided above the stacker. However, by providing the stacker above the pocket, it becomes possible for the transporting path from the reversal driving roller to the stacker to be made straight, thereby preventing the sheet jamming phenomenon even more effectively.

Various other modifications may also be conceived without departing from the spirit of the present invention.

Industrial Applicability

With the sheet discriminating/counting machine and sheet discriminating/counting method according to the present invention, sheets of multiple countries or regions can be subjected to the discriminating/counting processing, and further, the space formed inside the counting machine main unit is effectively and aggressively utilized as a transporting path so that the length of the transporting path can be made sufficiently long, thus making small and compact the sheet discriminating/counting machine, and in addition, sheets can be subjected to the sheet discriminating/counting at high speed even with small and compact sheet discriminating/counting machines. Furthermore, the jammed sheets and residual sheets can be extracted and removed in a simple and easy manner by opening the transporting paths. A photo-transmission type line sensor making up the sheet discriminating unit on the straight transporting path is provided so as to traverse the transporting path to thereby serially scan the photoreceptor rows of the line sensor with a scanning processing circuit, and repeating this serial scanning enables the speedy and precise scanning of the entire surface of the sheets, so that the sheet discriminating/counting, and further, the denomination determination and counting of bills, the detection of whether the bill is whole or not, whether the bill is folded or not, and so forth, can be performed in an accurate and speedy manner. High-speed processing is enabled, and also, the load on the control CPU can be reduced, thereby handling increased speeds of the sheet discriminating/counting processing. The control CPU and computation CPU are included, so that a part of the control CPU is handed by the computation CPU, thereby reducing the processing load of the control CPU, whereby the discriminating/counting processing speed can be improved, and also the processing load on the control CPU is even further reduced, so that speed of the sheet discrimination processing can be increased even further. Thus, the sheet discriminating/counting machine and sheet discriminating/counting method according to the present invention has great possibilities for industrial applicability.

1. A sheet discriminating/counting machine comprising:
a hopper to which sheets to be discriminated are supplied;
a sheet transporting device for transporting sheets supplied to the hopper one by one along a transporting path with a shorter side of each sheet parallel to a transporting direction;
a sheet discriminating unit disposed along the transporting path for discriminating/counting sheets;
a stacker upon which sheets fed out from the transporting path are stacked; and
discrimination object selecting means for selecting a discriminating program for performing discrimination processing of the sheets to be discriminated;
said transporting path including a curved transporting region which is curved in a U-shape on the way from the hopper to the stacker.

2. A sheet discriminating/counting machine according to claim 1, wherein said discrimination object selecting means includes: activation-time discrimination object selecting means for selecting and setting a discriminating program in order to determine sheets to be discriminated at the time of activation; and in-operation discrimination object switching means for selectively switching discriminating programs for discrimination processing of desired sheets to be discriminated during operation, and wherein control processing of a control CPU and discrimination processing of a computation CPU are respectively executed based on a control program and a selected discriminating program.

3. A sheet discriminating/counting machine according to claim 1, wherein said hopper is formed on an apex of the counting machine main unit, the stacker is formed on the lower front portion of the counting machine main unit, said U-shaped curved transporting region is formed at the lower rear side of the counting machine main unit, and said transporting path is composed of a combination of a straight transporting path from the hopper to the U-shaped curved transporting region, the U-shaped curved transporting region, and a downstream side transporting path to the stacker.

4. A sheet discriminating/counting machine according to claim 3, further comprising a sheet discriminating unit for performing discriminating/counting and genuine/forged determination of sheets, disposed along the straight transporting path, said sheet discriminating unit being provided with a line sensor so as to traverse the transporting path, and wherein the line sensor is a photo-transmission sensor in which a projection side sensor member and reception side sensor member are assembled so as to be separable into two parts, configured so as to perform discriminating scanning of the entire surface of sheets transported along the transporting path by repeating the line scanning.

5. A sheet discriminating/counting machine according to claim 4, further comprising a rear side transporting path opening mechanism at the rear side of the straight transporting path, disposed around a lower support shaft of the counting machine main unit, said rear side transporting path opening mechanism including a rear opening guide arm mechanism turnable around a support shaft provided to the lower front side of the U-shaped curved transporting region, and said opening guide arm mechanism including guide plates so that each of the straight transporting path and the U-shaped curved transporting region is opened.

6. A sheet discriminating/counting machine according to claim 3, wherein said downstream side transporting path is crest-shaped, a crest-shaped transporting path opening mechanism turning on a lower support shaft of the counting machine main unit is disposed below the downstream side transporting path, said crest-shaped transporting path opening mechanism includes a front opening guide arm mechanism turning on a support shaft provided at the lower front side of the U-shaped curved transporting region, and said opening guide arm mechanism includes a guide plate making up the downstream side transporting path so as to be opened.

7. A sheet discriminating/counting machine according to claim 3, wherein said downstream side transporting path is crest-shaped, a reject transporting path opening mechanism for opening a reject transporting path is provided below a reject transporting path branching from the apex side of the downstream side transporting path, and said reject transporting path opening mechanism includes a opening guide arm mechanism provided turnably around a center-lower side support shaft of the counting machine main unit, with the opening guide arm mechanism being provided with a guide plate making up the reject transporting path so as to be opened.

8. A sheet discriminating/counting machine comprising:
a hopper to which sheets to be discriminated and counted are supplied;
a sheet transporting device for transporting sheets supplied to the hopper one by one along a transporting path with a shorter side of each sheet parallel to a transporting direction;
a sheet discriminating unit disposed along the transporting path for discriminating/counting sheets;
a sterilizing processing device disposed along the transporting path for sterilizing or disinfecting processing of the transported sheets; and
a stacker upon which sheets fed out from the transporting path are stacked,
said transporting path including a curved transporting region which is curved in a U-shape on the way from the hopper to the stacker.

9. A sheet discriminating/counting method comprising the steps of:
selecting a discriminating program by discrimination object selecting means, corresponding to sheets to be discriminated in order to perform discrimination processing of desired sheets to be discriminated;
feeding sheets, to be discriminated, stacked onto a hopper on a transporting path by a feeding mechanism at a feeding rate of 1200 sheets per minute or faster, in order to perform discrimination processing of the sheets to be discriminated with a computation CPU, based on the control processing of a control CPU and the selected discriminating program;
guiding the fed sheets to a straight transporting path descending along a rear side of the counting machine main unit;
performing discrimination/counting and genuine/forged determination of the sheets by a sheet discrimination unit based on the discriminating program of the computation CPU while the sheets passing through the straight transporting path;
guiding the sheets subjected to discrimination/counting by the sheet discrimination unit to a downstream side transporting path through a U-shaped curved transporting region at the lower rear side of the counting machine main unit; and
stacking the sheet sent out from the downstream side transporting path to a stacker.

10. A sheet discriminating/counting method according to claim 9, wherein the downstream side transporting path is a crest-shaped transporting path and a reject transporting path branches from the apex thereof, and wherein, sheets which are not an object of discrimination among the sheets subjected to discrimination/counting at the sheet discrimination unit are guided to the reject transporting path, sent out to the pocket and then stacked.

11. A sheet discriminating/counting method according to claim 9, wherein, during operation of the sheet discriminating/counting machine, the discriminating program recorded in SRAM is switched over by in-operation discrimination object switching means, and on the other hand, discrimination processing of the computation CPU based on the discriminating program switched over and control processing of the control CPU based on the control program are performed, thereby performing discrimination/counting processing of the sheets transported along the transporting path.
